(19) United States
(12) Patent Application Publication
(10) Pub. No.: US 2026/0231660 A1
(43) Pub. Date: Aug. 6, 2026

(54) DISPLAY DEVICE AND ELECTRONIC DEVICE INCLUDING THE SAME

(71) Applicant: Samsung Display Co., Ltd., Yongin-si (KR)

(72) Inventor: Sang Ho KIM, Yongin-si (KR)

(21) Appl. No.: 19/309,380

(22) Filed: Aug. 25, 2025

(30) Foreign Application Priority Data
Feb. 3, 2025 (KR) 10-2025-0013062

(51) Int. Cl. H10K 59/80; G02F 1/01; G06F 3/01; G09G 3/3233

(52) U.S. Cl. CPC H10K 59/8793; G02F 1/0136; G06F 3/013; G09G 3/3233; H10K 59/879; G09G 2300/0819; G09G 2300/0852; G09G 2300/0861; G09G 2354/00

(57) ABSTRACT

A display device and an electronic device including the display device are provided. The display device includes a display panel emitting light and a variable focus module arranged on one surface of the display panel and adjusting a focal length of the light. The variable focus module includes a first polarization control layer emitting incident light as first circularly polarized light or second circularly polarized light and a geometric phase lens functioning as a convex lens having a first focal length if (e.g., when) the first circularly polarized light is incident, and functioning as a concave lens having a second focal length if (e.g., when) the second circularly polarized light is incident.

### CROSS-REFERENCE TO RELATED APPLICATION

The present application claims priority to and the benefit of Korean Patent Application No. 10-2025-0013062, filed on Feb. 3, 2025, in the Korean Intellectual Property Office, the entire content of which is incorporated herein by reference.

### BACKGROUND

### 1. Field

One or more embodiments of the present disclosure relate to a display device and an electronic device including the same.

### 2. Description of the Related Art

A head mounted display (HMD) is an image display device that is worn on a user's head in the form of glasses or a helmet, and is configured to focus images at a distance close to the user's eyes. HMDs may be used to implement virtual reality (VR) or augmented reality (AR) environments.).

A head mounted display enlarges and displays an image displayed on a small display device utilizing a plurality of lenses. Therefore, a display device applied to the head mounted display needs to provide a high-resolution image, for example, an image having a resolution of about 3000 pixels per inch (PPI) or higher. To this end, organic light emitting diode on silicon (OLEDoS), which is a high-resolution small-sized organic light emitting display device, may be used as the display device applied to the head mounted display. The OLEDoS is a device that displays an image through organic light emitting diodes (OLEDs) arranged on a semiconductor wafer substrate including a complementary metal oxide semiconductor (CMOS) circuitry.

In related art HMDs, the image displayed on the display device is magnified and presented to the user's eyes through a pancake lens having a fixed focal length. Under such conditions, the user may experience visual fatigue due to a mismatch in focus when viewing near and far objects in a virtual environment. This mismatch may lead to discomfort or even cybersickness, such as visually induced motion sickness.

### SUMMARY

One or more aspects of embodiments of the present disclosure are directed toward a display device capable of reducing or preventing an occurrence of fatigue in the user's eyes due to the mismatch in focus when viewing near and far objects in a virtual reality image, and an electronic device including the same.

However, aspects of the present disclosure are not restricted to those set forth herein. The above and additional aspects of the present disclosure will become more apparent to one of ordinary skill in the art to which the present disclosure pertains by referencing the detailed description of the present disclosure provided herein or by practicing the presented embodiments of the disclosure.

According to one or more embodiments of the present disclosure, a display device includes a display panel emitting light and a variable focus module on (e.g., arranged on) a (e.g., one) surface of the display panel and adjusting a focal length of the light. The variable focus module includes a first polarization control layer emitting incident light as first circularly polarized light or second circularly polarized light and a geometric phase lens functioning as a convex lens having a first focal length if (e.g., when) the first circularly polarized light is incident, and functioning as a concave lens having a second focal length if (e.g., when) the second circularly polarized light is incident.

In one or more embodiments, the variable focus module may further include a second polarization control layer emitting the first circularly polarized light or the second circularly polarized light incident from the geometric phase lens as the second circularly polarized light.

The light emitted from the display panel may be first linearly polarized light having an optical axis in a first direction, and the first polarization control layer may include a first polarization conversion layer emitting the first linearly polarized light as it is or converting the first linearly polarized light into second linearly polarized light having an optical axis in a second direction orthogonal to the first direction and a first phase delay layer emitting the first circularly polarized light by delaying a phase of the first linearly polarized light, or emitting the second circularly polarized light by delaying a phase of the second linearly polarized light.

The second polarization control layer may include a second phase delay layer emitting the first linearly polarized light by delaying a phase of the first circularly polarized light incident from the geometric phase lens, or emitting the second linearly polarized light by delaying a phase of the second circularly polarized light, a second polarization conversion layer emitting the first linearly polarized light incident from the second phase delay layer as it is or converting the second linearly polarized light into the first linearly polarized light, and a third phase delay layer emitting the second circularly polarized light by delaying the phase of the first linearly polarized light emitted from the second polarization conversion layer.

The display panel may include a linear polarizer emitting light emitted from inside the display panel or light incident from outside the display panel as linearly polarized light vibrating in one direction and a fourth phase delay layer delaying a phase of the linearly polarized light or a circularly polarized light.

In one or more embodiments, the display device may further include a pancake lens magnifying an image implemented on the display panel.

The pancake lens may include a semitransparent mirror transmitting a portion of light incident on the pancake lens and reflecting another portion of the light, a first lens on (e.g., arranged on) the semitransparent mirror, a second lens on (e.g., arranged on) the first lens, a fifth phase delay layer on (e.g., arranged on) a (e.g., one) surface of the second lens and having a phase delay of λ/4, a reflective polarizing layer on (e.g., arranged on) the fifth phase delay layer, transmitting light parallel to a transmission axis, and reflecting light orthogonal to the transmission axis, and a third lens on (e.g., arranged on) the reflective polarizing layer.

In one or more embodiments, the display device may further include an eye tracking module. The display panel may include a plurality of display areas, the eye tracking module determines which area among the plurality of display areas a gaze of an eye is directed to, and tracks a depth of the gaze, and the variable focus module includes a plurality of variable focus areas respectively corresponding to the plurality of display areas, and adjusts a focal length of a variable focus area determined by the eye tracking module as an area that the eye is not gazed at among the plurality of variable focus areas according to the depth of the gaze.

In one or more embodiments, the light emitted from the display panel may be first linearly polarized light having an optical axis in a first direction, and the variable focus module may include a first polarization conversion layer emitting the first linearly polarized light as it is according to a first driving voltage, or converting the first linearly polarized light into second linearly polarized light having an optical axis in a second direction orthogonal to the first direction according to a second driving voltage, a first phase delay layer emitting first circularly polarized light by delaying a phase of the first linearly polarized light, or emitting second circularly polarized light by delaying a phase of the second linearly polarized light and a geometric phase lens functioning as a convex lens having a first focal length if (e.g., when) the first circularly polarized light is incident, and functioning as a concave lens having a second focal length if (e.g., when) the second circularly polarized light is incident.

The eye tracking module may further include a variable focus circuit applying the first driving voltage to the first polarization conversion layer if (e.g., when) the depth of the gaze is greater than a first threshold value, and applying the second driving voltage to the first polarization conversion layer if (e.g., when) the depth of the gaze is less than or equal to the first threshold value.

The variable focus area determined by the eye tracking module may be defined as a gaze area, and the variable focus area not determined by the eye tracking module is defined as a non-gaze area. If (e.g., when) the first driving voltage is applied to the first polarization conversion layer of the gaze area, the second driving voltage may be applied to the first polarization conversion layer of a plurality of non-gaze areas, or if (e.g., when) the second driving voltage is applied to the first polarization conversion layer of the gaze area, the first driving voltage may be applied to the first polarization conversion layer of the plurality of non-gaze areas.

If (e.g., when) the depth of the gaze is greater than the first threshold value, the variable focus module of the variable focus area determined by the eye tracking module may have the first focal length, and if (e.g., when) the depth of the gaze is less than or equal to the first threshold value, the variable focus module of the variable focus area determined by the eye tracking module may have the second focal length.

The first polarization conversion layer may include first and second substrates opposite to (e.g., facing) each other, a plurality of first pixel electrodes on (e.g., arranged on) a (e.g., one) surface of the first substrate opposite to (e.g., facing) the second substrate and respectively corresponding to the plurality of variable focus areas, a first common electrode on (e.g., arranged on) a (e.g., one) surface of the second substrate opposite to (e.g., facing) the first substrate and overlapping the plurality of variable focus areas, and a first liquid crystal layer between (e.g., arranged between) the first substrate and the second substrate.

The variable focus module may further include a second phase delay layer emitting the first linearly polarized light by delaying a phase of the first circularly polarized light incident from the geometric phase lens, or emitting the second linearly polarized light by delaying a phase of the second circularly polarized light, a second polarization conversion layer emitting the first linearly polarized light incident from the second phase delay layer as it is or converting the second linearly polarized light into the first linearly polarized light, and a third phase delay layer emitting the second circularly polarized light by delaying the phase of the first linearly polarized light emitted from the second polarization conversion layer.

The second polarization conversion layer may include third and fourth substrates opposite to (e.g., facing) each other, a plurality of second pixel electrodes on (e.g., arranged on) a (e.g., one) surface of the third substrate opposite to (e.g., facing) the fourth substrate and respectively corresponding to the plurality of variable focus areas, a second common electrode on (e.g., arranged on) a (e.g., one) surface of the fourth substrate opposite to (e.g., facing) the third substrate and overlapping the plurality of variable focus areas, and a second liquid crystal layer between (e.g., arranged between) the third substrate and the fourth substrate.

The variable focus module may include a plurality of sub-variable focus modules overlapping each other in a thickness direction of the display panel.

According to one or more embodiments of the present disclosure, there is provided a method for driving a display device. The method includes obtaining gaze information of both (e.g., simultaneously) eyes of a user, determining a gaze area of the user and calculating a gaze depth based on the obtained gaze information, adjusting incident light to a first focal length in a variable focus area corresponding to the gaze area of the user among a plurality of variable focus areas of a variable focus module if (e.g., when) the gaze depth is greater than a threshold value, and adjusting the incident light to a second focal length in the variable focus area corresponding to the gaze area of the user if (e.g., when) the gaze depth is less than or equal to the threshold value.

A variable focus area other than the gaze area of the user may be defined as a non-gaze area, and the method may further include adjusting the incident light to the second focal length in a plurality of non-gaze areas if (e.g., when) the gaze depth is greater than the threshold value, and adjusting the incident light to the first focal length in a plurality of non-gaze areas if (e.g., when) the gaze depth is less than or equal to the threshold value.

The first focal length may correspond to a focal length of a virtual image, and the second focal length may correspond to a focal length of a real image.

According to one or more embodiments of the present disclosure, an electronic device includes a display module displaying an image and a processor transmitting a video data signal to the display module. The display module includes a display panel emitting light and a variable focus module on (e.g., arranged on) a (e.g., one) surface of the display panel and adjusting a focal length of the light, and the variable focus module includes a first polarization control layer emitting incident light as first circularly polarized light or second circularly polarized light and a geometric phase lens functioning as a convex lens having a first focal length if (e.g., when) the first circularly polarized light is incident, and functioning as a concave lens having a second focal length if (e.g., when) the second circularly polarized light is incident.

The display device and the electronic device including the same according to one or more embodiments of the present disclosure, may reduce or prevent the occurrence of fatigue in the user's eyes due to the mismatch in focus when viewing the near and far objects in the virtual reality image by varying a focal length in a corresponding variable focus area of the variable focus module depending on whether the user gazes at a near or far distance in the display area. For example, the desired effects may be achieved by varying the focal length in a corresponding variable focus area of a variable focus module, depending on whether the user is gazing at a near or far distance within the display area. For example, the desired effects may be realized by dynamically adjusting the focal length in a specific variable focus area of the variable focus module based on real-time gaze tracking data. In particular, the system determines the user's gaze direction and depth, and selectively modifies the optical characteristics of the display—such as switching between convex and concave lens functions—by utilizing polarization control and geometric phase lens technology. This adaptive focusing mechanism enables the display to present images at varying depths that more closely align with the user's natural accommodation response, thereby enhancing visual comfort and reducing symptoms such as eye strain, blurred vision, and cybersickness. Moreover, by integrating this adaptive focus technology with eye-tracking and multi-zone display control, the system may provide a more immersive and personalized visual experience. For instance, the gaze area may be rendered with a focal length enhanced for the user's current depth of focus, while non-gaze areas are adjusted accordingly to maintain visual coherence and reduce unnecessary power consumption or processing overhead. These features may be implemented through the inclusion of a variable focus module including a first polarization control layer and a geometric phase lens, and a processor configured to control focal length adjustments based on gaze depth.

However, the effects and aspects of embodiments of the present disclosure are not restricted to the ones set forth herein. The above and other effects and aspects of the embodiments will become more apparent to one of ordinary skill in the art to which the present disclosure pertains by referencing the following descriptions and the appended claims.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is a block diagram of an electronic display device according to one or more embodiments of the present disclosure;

FIG. 2 illustrates schematic diagrams illustrating electronic devices according to one or more embodiments of the present disclosure;

FIG. 3 is an exploded perspective view illustrating a display device according to one or more embodiments of the present disclosure;

FIG. 4 is a block diagram illustrating a display device according to one or more embodiments of the present disclosure;

FIG. 5 is an equivalent circuit diagram of a first sub-pixel according to one or more embodiments of the present disclosure;

FIG. 6 is a schematic plan view illustrating an example of a display panel according to one or more embodiments of the present disclosure;

FIG. 7 is an enlarged plan view of an example of the display area of FIG. 6 according to one or more embodiments of the present disclosure;

FIG. 8 illustrates a modified example of FIG. 7 according to one or more embodiments of the present disclosure;

FIG. 9 is a cross-sectional view illustrating an example of the display panel taken along the line X1-X1′ of FIG. 7 according to one or more embodiments of the present disclosure;

FIG. 10 is a cross-sectional view illustrating an example of the display panel taken along the line X-X1′ of FIG. 7 according to one or more embodiments of the present disclosure;

FIG. 11 is a view for describing a detailed structure of a variable focus module, and a polarization direction and travel path of light in a light emitting element, a polarizing member, and a variable focus module of the display panel when a fourth driving voltage and a sixth driving voltage are applied to a first polarization conversion layer LC1 and a second polarization conversion layer LC2 according to one or more embodiments of the present disclosure;

FIG. 12 is a view for describing a detailed structure of a variable focus module, and a polarization direction and travel path of light in a light emitting element, a polarizing member, and a variable focus module of the display panel when a fifth driving voltage and a seventh driving voltage are applied to a first polarization conversion layer LC1 and a second polarization conversion layer LC2 according to one or more embodiments of the present disclosure;

FIG. 13 is a view for describing a detailed structure of a pancake lens of FIGS. 9 to 12 and a travel path of light in the pancake lens according to one or more embodiments of the present disclosure;

FIG. 14 is a perspective view illustrating a plurality of display areas of a display device and a plurality of variable focus areas of a variable focus module according to one or more embodiments of the present disclosure;

FIG. 15 is a cross-sectional view illustrating an example of the variable focus module taken along the line X2-X2′ of FIG. 14 according to one or more embodiments of the present disclosure;

FIG. 16 is a flowchart illustrating a method for driving a head mounted display device according to one or more embodiments of the present disclosure;

FIG. 17 is a view illustrating a user gazing at one selected from among the plurality of variable focus areas according to one or more embodiments of the present disclosure;

FIG. 18 is a cross-sectional view illustrating an example of the display panel taken along the line X1-X1′ of FIG. 7 according to one or more embodiments of the present disclosure;

FIG. 19 is a perspective view illustrating a head mounted display device according to one or more embodiments of the present disclosure;

FIG. 20 is an exploded perspective view illustrating an example of the head mounted display device of FIG. 17 according to one or more embodiments of the present disclosure; and

FIG. 21 is a perspective view illustrating a head mounted display device according to one or more embodiments of the present disclosure.

### DETAILED DESCRIPTION

Aspects of embodiments of the present disclosure and methods of accomplishing the same may be understood more readily by reference to the detailed description of embodiments and the accompanying drawings. Hereinafter, example embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure might not be described for conciseness.

Unless otherwise noted, like reference numerals, characters, or combinations thereof denote like elements throughout the attached drawings and the written description, and thus, duplicative descriptions thereof will not be repeated. Further, parts not related to the description of one or more embodiments might not be shown to make the description clear and conciseness.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure.

In the detailed description, for the purposes of explanation, numerous specific details are set forth to provide a thorough understanding of one or more embodiments of the disclosure. It is apparent, however, that one or more embodiments may be practiced without these specific details or with one or more equivalent arrangements. In other instances, well-suitable and/or established structures and devices are shown in block diagram forms to avoid unnecessarily obscuring one or more described embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the drawings. It will be understood that the spatially relative terms are intended to encompass different orientations of the device in use or in operation, in addition to the orientation depicted in the drawings. For example, if a device in the drawings is turned over, for example, upside down, elements described as “below” or “beneath” or “under” other elements or features would then be oriented “above” the other elements or features. Thus, the example terms “below” and “under” may encompass both (e.g., simultaneously) an orientation of above and below. The device may be otherwise oriented (e.g., rotated 90 degrees or at other orientations), and the spatially relative descriptors used herein should be interpreted accordingly. Similarly, if (e.g., when) a first part is described as being arranged “on” a second part, this indicates that the first part may be arranged at an upper side or a lower side of the second part without the limitation to the upper side thereof on the basis of the gravity direction.

Further, in this disclosure, the phrase “on a plane,” or “in plan view,” refers to viewing a target portion from the top, and the phrase “on a cross-section” refers to viewing a cross-section formed by vertically cutting a target portion from a side.

It will be understood that if (e.g., when) an element, layer, region, or component is referred to as being “formed on,” “on,” “connected to,” or “coupled to” another element, layer, region, or component, it may be directly formed on, on, connected to, or coupled to the other element, layer, region, or component, or indirectly formed on, on, connected to, or coupled to the other element, layer, region, or component such that one or more intervening elements, layers, regions, or components may be present therebetween. For example, if (e.g., when) a layer, region, or component is referred to as being “electrically connected” or “electrically coupled” to another layer, region, or component, it may be directly electrically connected or coupled to the other layer, region, and/or component or one or more intervening layers, regions, or components may be present therebetween. However, “directly connected/directly coupled” refers to one component directly connecting or coupling another component without an intermediate component. In one or more embodiments, other expressions describing relationships between components, such as “between,” “immediately between” or “adjacent to” and “directly adjacent to” may be construed similarly. In addition, it will also be understood that if (e.g., when) an element or layer is referred to as being “between” two elements or layers, it may be the only element or layer between the two elements or layers, or one or more intervening elements or layers may also be present.

For the purposes of the present disclosure, expressions, such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” “at least one selected from among X, Y, and Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” when describing embodiments of the present disclosure refers to “one or more embodiments of the present disclosure”.

It will be understood that, although the terms “first,” “second,” “third,” and/or the like, may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described below could be termed a second element, component, region, layer, or section, without departing from the spirit and scope of the present disclosure.

In the example embodiments, the x-axis, the y-axis, and/or the z-axis are not limited to three axes of a cubic coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” and “one” and “the” are intended to include the plural forms as well, unless the context clearly indicates otherwise. It will be further understood that the terms “comprise(s),” “comprising,” “have(has),” “having,” “include(s),” and “including,” if (e.g., when) used in this disclosure, specify the presence of the stated features, numbers, steps, operations, elements, and/or components, but do not preclude the presence or addition of one or more other features, numbers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and refers to within an acceptable range of deviation for the particular value as determined by one of ordinary skill in the art, considering the measurement in question and the error associated with measurement of the particular quantity (i.e., the limitations of the measurement system). For example, “about” may refer to within one or more standard deviations, or within ±30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

If (e.g., when) one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this disclosure such that amending to expressly recite any such subranges would comply with the requirements of 35 U.S.C. § 112(a) and 35 U.S.C. § 132(a).

The light emitting elements, the display panel/device, the electronic or electric devices, and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the one or more suitable components of these devices may be formed on one integrated circuit (IC) chip or on separate IC chips. Further, the one or more suitable components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present disclosure, and should not be interpreted in an idealized or overly formal sense, unless expressly so defined herein.

A display device according to one or more embodiments may be applied to one or more suitable electronic devices. An electronic device according to one or more embodiments may include the display device described herein, and may further include a module or device having additional functions in addition to the display device.

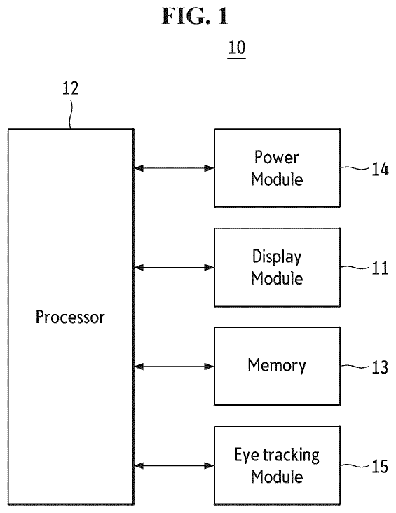

FIG. 1 is a block diagram of an electronic device according to one or more embodiments of the present disclosure. Referring to FIG. 1, an electronic device 10 according to one or more embodiments may include a display module 11, a processor 12, a memory 13, a power module 14, and an eye tracking module 15.

The processor 12 may include at least one of a central processing unit (CPU), an application processor (AP), a graphic processing unit (GPU), a communication processor (CP), an image signal processor (ISP), or a controller.

Data information necessary for an operation of the processor 12 and/or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power desired or required for an operation of the electronic device 10.

The eye tracking module 15 is a module that tracks where each of user's two eyes gazes. The eye tracking module 15 may include an infrared sensor or a camera, and a variable focus circuit, and may obtain information on a pupil of each of the user's eyes using the infrared sensor or the camera. For example, if (e.g., when) infrared light is shone into the user's eye, a reflection may occur on the cornea, and such reflected light may be captured by the infrared sensor/camera along with the pupil. Through this, the eye tracking module 15 may track a position of the eyes, movement of the pupils, and a depth of gaze. The eye tracking module 15 may determine the position of the display device 11 at which the user gazes and the depth of the gaze by analyzing the information on the pupil of each of the user's eyes obtained from an eye tracking device. The variable focus circuit may apply a set voltage to a variable focus module according to one or more embodiments based on the determined gaze area and depth of the gaze. The eye tracking module 15 may be implemented as a device that uses any suitable eye tracking technology.

At least one of the components of the electronic device 10 described above may be included in the display device according to one or more embodiments. In addition, some of the individual modules functionally included within one module may be included within the display device, while others may be provided separately from the display device. For example, the display device may include the display module 11, and the processor 12, the memory 13, the power module 14, and the eye tracking module 15 may be provided in the form of other devices within the electronic device 10 other than the display device.

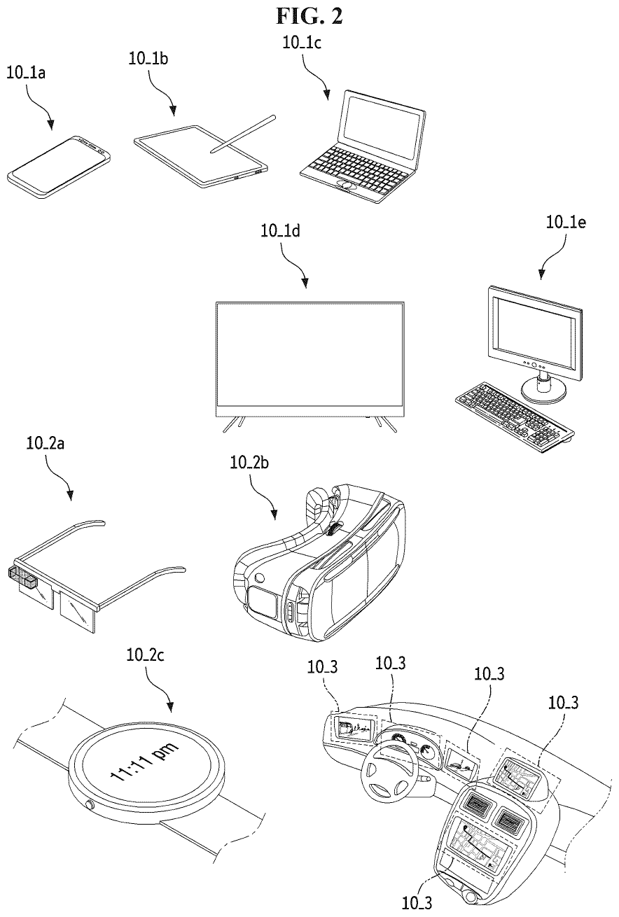

FIG. 2 illustrates schematic diagrams of electronic devices according to one or more embodiments of the present disclosure;

Referring to FIG. 2, one or more suitable electronic devices to which the display device according to one or more embodiments is applied may include not only an image display electronic device such as a smart phone 10_1a, a tablet PC 10_1b, a laptop 10_1c, a TV 10_1d, and a desk monitor 10_1e, but also a wearable electronic device including a display module such as a smart glasses 10_2a, a head mounted display 10_2b, a smart watch 10_2c, and/or the like, and/or a vehicle electronic device 10_3 including a display module such as a Center Information Display (CID), a room mirror display, and/or the like, arranged on a vehicle's instrument panel, center fascia, or dashboard.

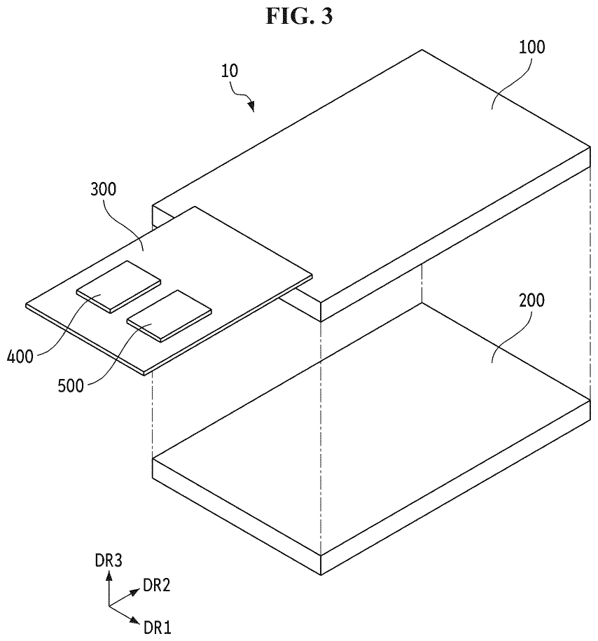

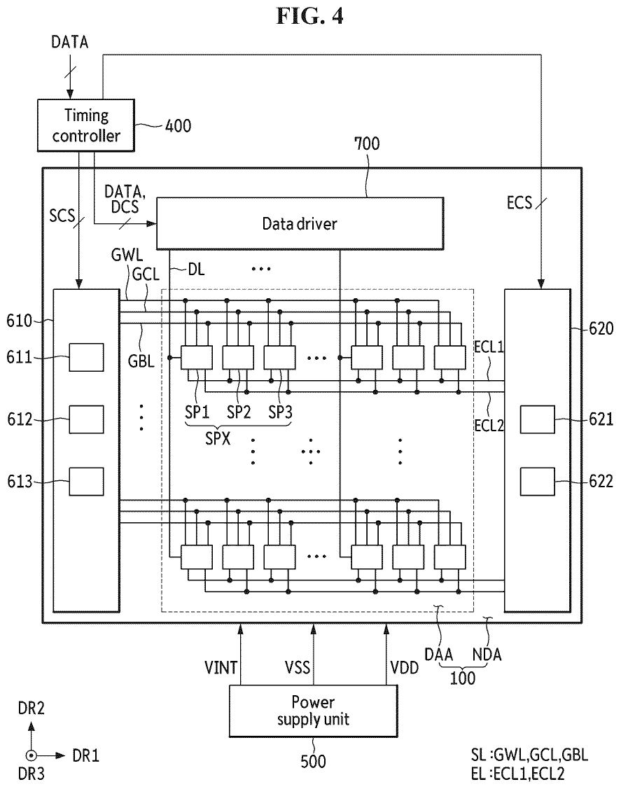

FIG. 3 is an exploded perspective view illustrating a display device according to one or more embodiments of the present disclosure. FIG. 4 is a block diagram illustrating the display device according to one or more embodiments of the present disclosure.

Referring to FIG. 3 and FIG. 4, a display device 10 according to one or more embodiments is a device displaying a moving/dynamic image or a still image. The display device 10 according to one or more embodiments may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to one or more embodiments may be applied to a display unit of a television, a laptop computer, a monitor, a billboard, or an Internet of Things (IoT) device. In one or more embodiments, the display device 10 may be applied to a smart watch, a watch phone, and/or a head mounted display (HMD) for implementing virtual reality and augmented reality.

The display device 10 according to one or more embodiments includes a display panel 100, a heat dissipation layer 200, a circuit board 300, a timing control circuit (also referred as timing controller) 400, and a power supply circuit (also referred as power supply unit) 500.

In one or more embodiments, the display panel 100 may be formed in a planar shape, for example, similar to a quadrangle. For example, the display panel 100 may have a planar shape, similar to a quadrangle, that has short sides in a first direction DR1 and long sides in a second direction DR2 intersecting the first direction DR1. In the display panel 100, a corner where the short side in the first direction DR1 and the long side in the second direction DR2 meet may be rounded to have a curvature or may be formed at a right angle. The planar shape of the display panel 100 is not limited to the quadrangle, and may be formed similarly to another polygon, a circle, or an oval. A planar shape of the display device 10 may follow the planar shape of the display panel 100, but embodiments of the present specification are not limited thereto.

The display panel 100 includes a plurality of pixels SPX (here reference characters “SPX” are used interchangeably with reference characters “PX”), a plurality of scan lines SL, a plurality of emission control lines EL, a plurality of data lines DL, a scan driver 610, a light emitting driver 620, and a data driver 700. The display panel 100 may be divided into a display area DAA displaying an image and a non-display area NDA that does not display an image, as illustrated in FIG. 4.

The plurality of pixels SPX may be arranged in the display area DAA. The plurality of pixels SPX may be arranged in a matrix form in the first direction DR1 and the second direction DR2. In one or more embodiments, the plurality of scan lines SL and the plurality of emission control lines EL may extend in the first direction DR1 and may be arranged in the second direction DR2. The plurality of data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

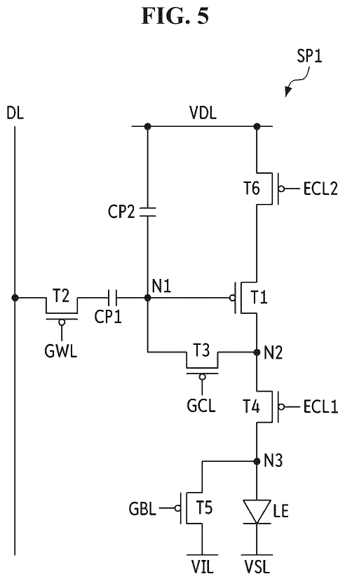

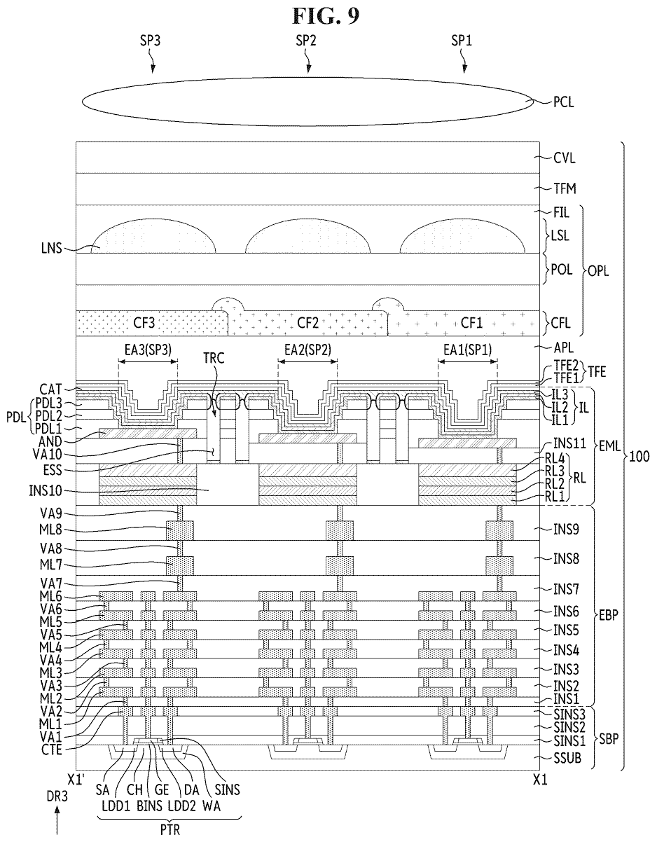

The plurality of pixels SPX include a plurality of sub-pixels SP1, SP2, and SP3. The plurality of sub-pixels SP1, SP2, and SP3 may each include a plurality of pixel transistors as illustrated in FIG. 5, and the plurality of pixel transistors may be formed through a semiconductor process and may be arranged on a semiconductor substrate (SSUB in FIG. 9). For example, in one or more embodiments, the plurality of pixel transistors of the data driver 700 may each be formed of a Complementary Metal Oxide Semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL according to a write scan signal of the write scan line GWL, and may be to emit light from a light emitting element according to the data voltage.

In one or more embodiments, the scan driver 610, the light emitting driver 620, and the data driver 700 may be arranged in the non-display area NDA.

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SSUB in FIG. 9). For example, in one or more embodiments, the plurality of scan transistors and the plurality of light emitting transistors may each be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines ECL1. The second emission control driver 622 may generate second emission control signals according to the emission timing control signal ECS and sequentially output the second emission control signals to the second emission control lines ECL2.

The data driver 700 may include a plurality of data transistors, and the plurality of data transistors may be formed through a semiconductor process and may be formed on a semiconductor substrate (SSUB in FIG. 9). For example, in one or more embodiments, the plurality of data transistors may each be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this regard, the sub-pixels SP1, SP2, and SP3 may be selected by the write scan signals of the scan driver 610, and the data voltages (e.g., converted analog data voltages) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, a rear surface of the display panel 100. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

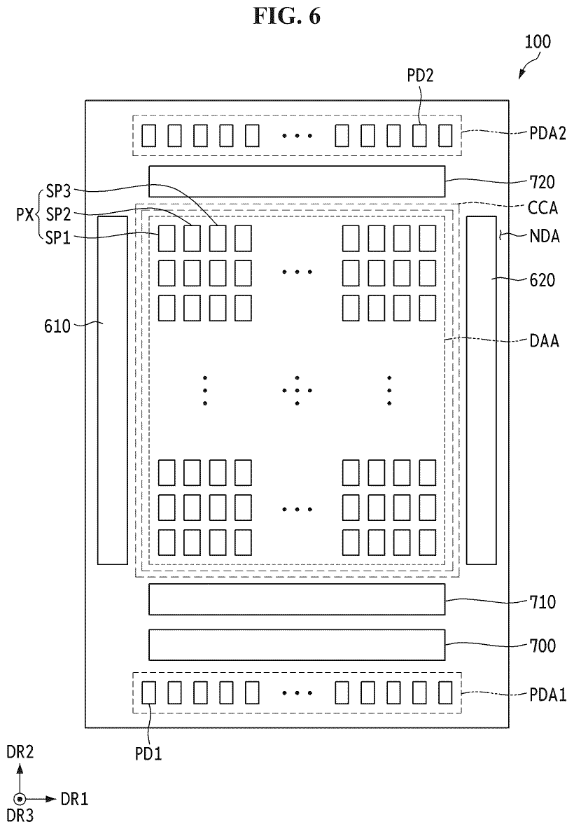

The circuit board 300 may be electrically connected to a plurality of first pads (PD1 in FIG. 6) of a first pad portion (PDA1 in FIG. 6) of the display panel 100 by using a conductive adhesive member such as an anisotropic conductive film. In one or more embodiments, the circuit board 300 may be a flexible printed circuit board or flexible film made of a flexible material. It is illustrated in FIG. 3 that the circuit board 300 is unfolded, but the circuit board 300 may be bent. In this regard, one end of the circuit board 300 may be arranged on the rear surface of the display panel 100 and/or a rear surface of the heat dissipation layer 200. The other end of the circuit board 300 may be connected to the plurality of first pads (PD1 in FIG. 6) of the first pad portion (PDA1 in FIG. 6) of the display panel 100 by using a conductive adhesive member. The one end of the circuit board 300 may be an end opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data DATA and the data timing control signal DCS to the data driver 700.

The power supply circuit 500 may generate a plurality of panel driving voltages according to a power voltage from the outside. For example, in one or more embodiments, the power supply circuit 500 may generate a first driving voltage VSS, a second driving voltage VDD, and a third driving voltage VINT and supply the generated driving voltages to the display panel 100. A description of the first driving voltage VSS, the second driving voltage VDD, and the third driving voltage VINT will be described later with reference to FIG. 5.

Each of the timing control circuit 400 and the power supply circuit 500 may be formed as an integrated circuit (IC) and attached to a (e.g., one) surface of the circuit board 300. In this regard, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the light emitting driver 620, and the data driver 700. In these embodiments, the timing control circuit 400 may include a plurality of timing transistors, and the power supply circuit 500 may include a plurality of power transistors. The plurality of timing transistors and the plurality of power transistors may be formed through a semiconductor process and may be formed on a semiconductor substrate (SSUB in FIG. 9). For example, in one or more embodiments, the plurality of timing transistors and the plurality of power transistors may be formed of CMOS, but embodiments of the present disclosure are not limited thereto. In one or more embodiments, each of the timing control circuit 400 and the power supply circuit 500 may be arranged between the data driver 700 and the first pad portion (PDA1 in FIG. 6).

FIG. 5 is an equivalent circuit diagram of a first sub-pixel according to one or more embodiments of the present disclosure.

Referring to FIG. 5, the first sub-pixel SP1 may be connected to a write scan line GWL, a control scan line GCL, a bias scan line GBL, a first emission control line ECL1, a second emission control line ECL2, and a data line DL. In addition, the first sub-pixel SP1 may be connected to a first driving voltage line VSL to which the first driving voltage VSS corresponding to a low potential voltage is applied, to a second driving voltage line VDL to which the second driving voltage VDD corresponding to a high potential voltage is applied, and to a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light according to a driving current flowing through a channel of a first transistor T1. An amount (e.g., emission intensity) of light emitted from the light emitting element LE may be proportional to the driving current. A first electrode of the light emitting element LE may be an anode electrode, and a second electrode of the light emitting element LE may be a cathode electrode. In one or more embodiments, the light emitting element LE may be an organic light emitting diode including a first electrode, a second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode. In these embodiments, the light emitting element LE may be a micro light emitting diode.

The first transistor T1 may be a driving transistor that controls a source-drain current (hereinafter, referred to as “driving current”) flowing between a source electrode and a drain electrode according to a voltage applied to a gate electrode.

A second transistor T2 may be arranged between one electrode of the first capacitor CP1 and the data line DL. The second transistor T2 is turned on by the write scan signal of the write scan line GWL and connects the one electrode of the first capacitor CP1 to the data line DL. Accordingly, the data voltage of the data line DL may be applied to the one electrode of the first capacitor CP1.

A third transistor T3 may be arranged between a first node N1 and a second node N2. The third transistor T3 is turned on by the write control signal of the write control line GCL and connects the first node N1 to the second node N2. Accordingly, if (e.g., when) a gate electrode and a drain electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line ECL1 and connects the second node N2 to the third node N3. Accordingly, the driving current of the first transistor T1 may be supplied to the light emitting element LE.

A fifth transistor T5 may be arranged between the third node N3 and the third driving voltage line VIL. The fifth transistor T5 is turned on by the bias scan signal of the bias scan line GBL and connects the third node N3 to the third driving voltage line VIL. Accordingly, the third driving voltage VINT of the third driving voltage line VIL may be applied to the first electrode of the light emitting element LE.

A sixth transistor T6 may be arranged between the source electrode of the first transistor T1 and the second driving voltage line VDL. The sixth transistor T6 is turned on by the second emission control signal of the second emission control line ECL2 and connects the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and a drain electrode of the second transistor T2. The second capacitor CP2 is formed between a gate electrode of the first transistor T1 and the second driving voltage line VDL.

Each of the first to sixth transistors T1 to T6 may be a metal-oxide-semiconductor field effect transistor (MOSFET). For example, in one or more embodiments, each of the first to sixth transistors T1 to T6 may be a P-type (kind) MOSFET, as shown in FIG. 5, but embodiments of the present disclosure are not limited thereto. In one or more embodiments, each of the first to sixth transistors T1 to T6 may be an N-type (kind) MOSFET. In one or more embodiments, each of some of the first to sixth transistors T1 to T6 may be a P-type (kind) MOSFET, and each of the remaining transistors may be an N-type (kind) MOSFET.

It is illustrated in FIG. 5 that the first sub-pixel SP1 includes the six transistors T1 to T6 and the two capacitors CP1 and CP2, but it should be noted that the equivalent circuit diagram of the first sub-pixel SP1 is not limited to that illustrated in FIG. 5. For example, the number of transistors and the number of capacitors of the first sub-pixel SP1 are not limited to that illustrated in FIG. 5.

In addition, an equivalent circuit diagram of a second sub-pixel SP2 and an equivalent circuit diagram of a third sub-pixel SP3 may be substantially the same as the equivalent circuit diagram of the first sub-pixel SP1 described with reference to FIG. 5. Therefore, the descriptions of the equivalent circuit diagram of the second sub-pixel SP2 and the equivalent circuit diagram of the third sub-pixel SP3 are not provided in the present disclosure.

FIG. 6 is a layout view illustrating an example of a display panel according to one or more embodiments of the present disclosure.

Referring to FIG. 6, the display area DAA of the display panel 100 according to one or more embodiments may include a plurality of pixels PX arranged in a matrix form. The non-display area NDA of the display panel 100 according to one or more embodiments may include a scan driver 610, a light emitting driver 620, a data driver 700, a first distribution circuit 710, a second distribution circuit 720, a first pad portion PDA1, and a second pad portion PDA2.

The scan driver 610 may be arranged on a first side of the display area DAA, and the light emitting driver 620 may be arranged on a second side (e.g., opposite the first side) of the display area DAA. For example, the scan driver 610 may be arranged on one side of the display area DAA in the first direction DR1, and the light emitting driver 620 may be arranged on the other side of the display area DAA in the first direction DR1. However, embodiments of the present disclosure are not limited thereto, for example, in one or more embodiments, the scan driver 610 and the light emitting driver 620 may be arranged on both (e.g., simultaneously) the first side and the second side of the display area DAA.

The first pad portion PDA1 may include a plurality of first pads PD1 connected to pads or bumps of the circuit board 300 through a conductive adhesive member. The first pad portion PDA1 may be arranged on a third side of the display area DAA. For example, the first pad portion PDA1 may be arranged on one side of the display area DAA in the second direction DR2. The first pad portion PDA1 may be arranged on the outside of the data driver 700 in the second direction DR2. In other words, the first pad portion PDA1 may be arranged such that it lies between the data driver 700 and the edge (outer boundary) of the display panel 100 in the second direction DR2.

The second pad portion PDA2 may include a plurality of second pads PD2 corresponding to test pads for testing whether the display panel 100 is normally operating. The plurality of second pads PD2 may be connected to a jig or probe pin or to a test circuit board during a test process. The test circuit board may be a printed circuit board made of a rigid material or a flexible printed circuit board made of a flexible material.

The second pad portion PDA2 may be arranged on a fourth side (opposite the third side) of the display area DAA. For example, the second pad portion PDA2 may be arranged on the other side of the display area DAA in the second direction DR2. The second pad portion PDA2 may be arranged on the outside of the second distribution circuit 720 in the second direction DR2. In other words, the second pad portion PDA2 may be arranged such that it lies between the second distribution circuit 720 and the edge (outer boundary) of the display panel 100 in the second direction DR2.

The first distribution circuit 710 distributes the data voltages applied through the first pad portion PDA1 to the plurality of data lines DL. For example, in one or more embodiments, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be arranged on the third side of the display area DAA of the display panel 100. For example, the first distribution circuit 710 may be arranged on one side of the display area DAA in the second direction DR2.

The second distribution circuit 720 distributes signals applied through the second pad portion PDA2 to the scan driver 610, the light emitting driver 620, and the data lines DL. The second pad portion PDA2 and the second distribution circuit 720 may be components for testing the operation of each pixel PX of the display area DAA. The second distribution circuit 720 may be arranged on the fourth side of the display area DAA of the display panel 100. For example, the second distribution circuit 720 may be arranged on the other side of the display area DAA in the second direction DR2. In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

A cathode connection portion CCA may be an area where a second electrode (CAT in FIG. 9) of a display element layer (EML in FIG. 9) is connected to the first driving voltage line VSL of the non-display area NDA. The cathode connection portion CCA may be arranged outside at least one side of the display area DAA. For example, in one or more embodiments, the cathode connection portion CCA may be arranged outside at least one selected from among the left, right, upper, and lower sides of the display area DA. In one or more embodiments, the cathode connection portion CCA may be arranged to be around (e.g., surround) the display area DA as illustrated in FIG. 6 to minimize or reduce a deviation in the first driving voltage VSS due to a voltage drop (IR drop) or voltage rising (IR rising) of the second electrode CAT in the display area DA.

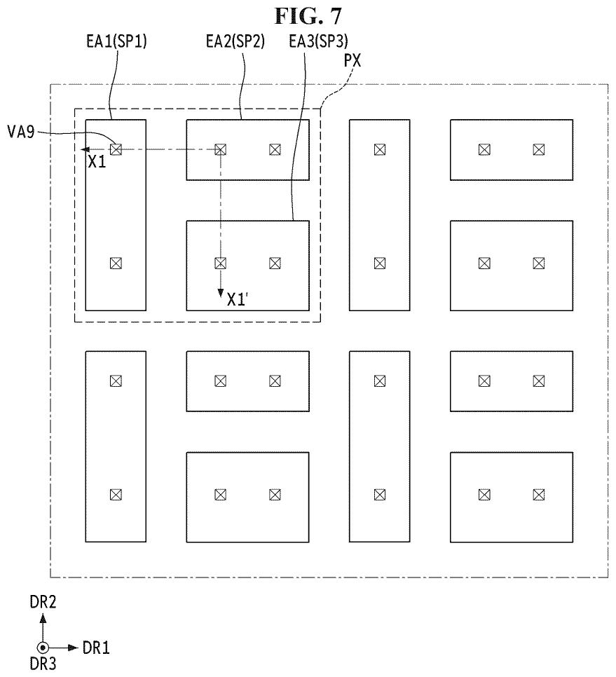

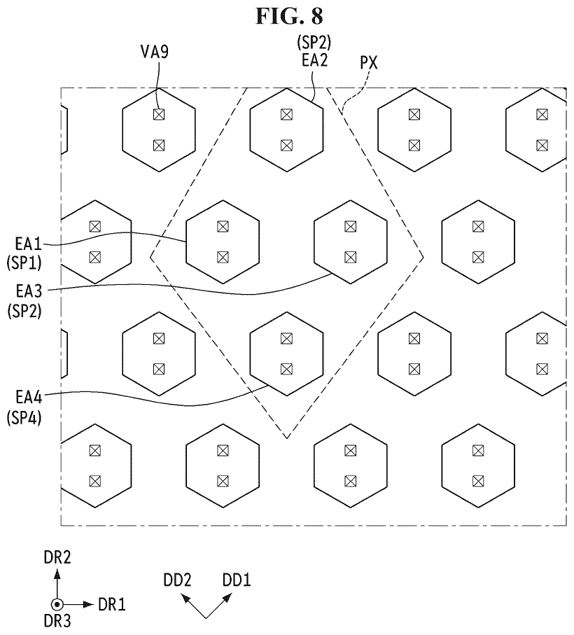

FIG. 7 is a layout view illustrating an example of the display area of FIG. 6 according to one or more embodiments of the present disclosure. FIG. 8 is a layout view illustrating another example of the display area of FIG. 6 according to one or more embodiments of the present disclosure.

Referring to FIGS. 7 and 8, in one or more embodiments, as shown in FIG. 7, each of the plurality of pixels PX includes a first light emitting area EA1, which is a light emitting area of the first sub-pixel SP1, a second light emitting area EA2, which is a light emitting area of the second sub-pixel SP2, and a third light emitting area EA3, which is a light emitting area of the third sub-pixel SP3. In one or more embodiments, as shown in FIG. 8, each of the plurality of pixels PX includes a first light emitting area EA1, which is a light emitting area of a first sub-pixel SP1, a second light emitting area EA2, which is a light emitting area of a second sub-pixel SP2, a third light emitting area EA3, which is a light emitting area of the a sub-pixel SP3, and a fourth light emitting area EA4, which is a light emitting area of a fourth sub-pixel SP4. Each of the first emission area EA1, the second emission area EA2, the third emission area EA3, and the fourth emission area EA4 may include a via VA9. The detailed descriptions of the via VA9 will be described in more detail later with reference to FIG. 9.

The first light emitting area EA1, the second light emitting area EA2, the third light emitting area EA3 and the fourth light emitting area EA4 may each have a quadrangular planar shape or a hexagonal planar shape as illustrated in FIGS. 7 and 8, but embodiments of the present disclosure are not limited thereto. The first light emitting area EA1, the second light emitting area EA2, the third light emitting area EA3, and the fourth emitting area EA4 may each have a planar shape other than the quadrangle or hexagon, such as a polygon, a circle, an ellipse, or an irregular shape.

As illustrated in FIG. 7, in each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different.

In one or more embodiments, as illustrated in FIG. 8, the light emitting areas EA1, EA2, EA3, and EA4 may each have a hexagonal planar shape. In these embodiments, the first light emitting area EA1 and the third light emitting area EA3 may be adjacent to each other in the first direction DR1, and the second light emitting area EA2 and the fourth light emitting area EA4 may be adjacent to each other in the second direction DR2. In addition, the first light emitting area EA1 and the second light emitting area EA2 may be adjacent to each other in a first diagonal direction DD1, and the second light emitting area EA2 and the third light emitting area EA3 may be adjacent to each other in a second diagonal direction DD2. In addition, the first light emitting area EA1 and the fourth light emitting area EA4 may be adjacent to each other in the second diagonal direction DD2, and the third light emitting area EA3 and the fourth light emitting area EA4 may be adjacent to each other in the first diagonal direction DD1. The first diagonal direction DD1, which is a direction between the first direction DR1 and the second direction DR2, may indicate a direction inclined by 45 degrees with respect to the first direction DR1 and the second direction DR2, and the second diagonal direction DD2 may be a direction perpendicular/orthogonal to the first diagonal direction DD1.

The first sub-pixel SP1 may be to emit first light, the second sub-pixel SP2 may be to emit second light, and the third sub-pixel SP3 may be to emit third light. In one or more embodiments, the first light may be light of a blue wavelength band, the second light may be light of a green wavelength band, and the third light may be light of a red wavelength band. For example, the blue wavelength band may indicate that a main peak wavelength of light is included in a wavelength band of approximately about 370 nm to about 460 nm, the green wavelength band may indicate that a main peak wavelength of light is included in a wavelength band of approximately about 480 nm to about 560 nm, and the red wavelength band may indicate that a main peak wavelength of light is included in a wavelength band of approximately about 600 nm to about 750 nm.

Each of the plurality of pixels PX may include three light emitting areas EA1, EA2, and EA3 as illustrated in FIG. 7 or may include four light emitting areas EA1, EA2, EA3, and EA4 as illustrated in FIG. 8. In this regard, the fourth light emitting area EA4 may be to emit a same second light as the second light emitting area EA2, but embodiments of the present disclosure are not limited thereto.

The light emitting areas of the plurality of pixels PX may be arranged in a stripe structure in which the light-emitting areas are arranged in the first direction DR1, a PenTile® structure in which the light emitting areas EA1, EA2, EA3, and EA4 are arranged in a rhombus shape as illustrated in FIG. 8, or a hexagonal structure in which the light emitting regions are arranged in a hexagonal shape. PenTile® is a duly registered trademark of Samsung Display Co., Ltd.

FIG. 9 is a cross-sectional view illustrating an example of the display panel taken along the line X1-X1′ of FIG. 7 according to one or more embodiments of the present disclosure.

Referring to FIG. 9, the display panel 100 includes a semiconductor backplane SBP, a light emitting element backplane EBP, a display element layer EML, an encapsulation layer TFE, an optical layer OPL, a cover layer CVL, and a variable focus module TFM.

The semiconductor backplane SBP includes a semiconductor substrate SSUB including a plurality of pixel transistors PTR, a plurality of semiconductor insulating films each covering the plurality of pixel transistors PTR, and a plurality of contact terminals CTE electrically connected to the plurality of pixel transistors PTR, respectively. The plurality of pixel transistors PTR may include (e.g., be) the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with first-type (kind) impurities. A plurality of well areas WA may be arranged in an upper surface of the semiconductor substrate SSUB. The plurality of well areas WA may be areas doped with second-type (kind) impurities. The second-type (kind) impurity may be different from the first-type (kind) impurity described above. For example, in one or more embodiments, if (e.g., when) the first-type (kind) impurity is a p-type (kind) impurity, the second-type (kind) impurity may be an n-type (kind) impurity. In one or more embodiments, if (e.g., when) the first-type (kind) impurity is an n-type (kind) impurity, the second-type (kind) impurity may be a p-type (kind) impurity.

Each of the plurality of well areas WA includes a source area SA corresponding to a source electrode of the pixel transistor PTR, a drain area DA corresponding to a drain electrode thereof, and a channel area CH arranged between the source area SA and the drain area DA.

A lower insulating film BINS may be arranged between the gate electrode GE and the well area WA. A side insulating film SINS may be arranged on a side surface of the gate electrode GE. The side insulating film SINS may be arranged on the lower insulating film BINS.

Each of the source area SA and the drain area DA may be an area doped with the first-type (kind) impurities. The gate electrode GE of the pixel transistor PTR may overlap the well area WA in the third direction DR3, which is a thickness direction of the semiconductor substrate SSUB. The channel area CH may overlap the gate electrode GE in the third direction DR3. The source area SA may be arranged on one side of the gate electrode GE, and the drain area DA may be arranged on the other side of the gate electrode GE.

Each of the plurality of well areas WA may further include a first low-concentration impurity area LDD1 arranged between the channel area CH and the source area SA and a second low-concentration impurity area LDD2 arranged between the channel area CH and the drain area DA. The first low-concentration impurity area LDD1 may be an area having an impurity concentration lower than that of the source area SA due to the lower insulating film BINS. The second low-concentration impurity area LDD2 may be an area having an impurity concentration lower than that of the drain area DA due to the lower insulating film BINS. A distance between the source area SA and the drain area DA may be increased by the first low-concentration impurity area LDD1 and the second low-concentration impurity area LDD2, which may increase a length of the channel area CH of each pixel transistor PTR.

A first semiconductor insulating film SINS1 may be arranged on the semiconductor substrate SSUB. A semiconductor insulating film SINS2 may be arranged on the first semiconductor insulating film SINS1.

The plurality of contact terminals CTE may be arranged on the second semiconductor insulating film SINS2. Each of the plurality of contact terminals CTE may be connected to any one of (e.g., a corresponding one among) the gate electrode GE, the source area SA, and the drain area DA of each of the plurality of pixel transistors PTR through a hole penetrating through the first semiconductor insulating film SINS1 and the second semiconductor insulating film SINS2. The plurality of contact terminals CTE may each independently include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof.

A third semiconductor insulating film SINS3 may be arranged on a side surface of each of the plurality of contact terminals CTE. An upper surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may independently be formed as an inorganic film of silicon nitride carbon (SiCN) or silicon oxide (SiOₓ) series, but embodiments of the present disclosure are not limited thereto.

In one or more embodiments, the semiconductor substrate SSUB may be replaced with a glass substrate or a polymer resin substrate such as polyimide. In these embodiments, thin film transistors may be arranged on the glass substrate or the polymer resin substrate. The glass substrate may be a rigid substrate that is not bent, and the polymer resin substrate may be a flexible substrate that may be bent or curved.

The light emitting element backplane EBP may include a plurality of conductive layers ML1 to ML8, a plurality of vias VA1 to VA9, and a plurality of insulating films INS1 to INS9. In addition, the light emitting element backplane EBP includes first to eighth conductive layers ML1 to ML8 arranged between the plurality of insulating films INS1 to INS9.

First to eighth insulating films INS1 to INS8 serve to insulate the first to eighth conductive layers ML1 to ML8. The first to eighth conductive layers ML1 to ML8 serve to implement the circuit of the first sub-pixel SP1 illustrated in FIG. 5 by connecting the plurality of contact terminals CTE exposed from the semiconductor backplane SBP.

For example, the first to sixth transistors T1 to T6 are merely formed on the semiconductor backplane SBP, and the first to sixth transistors T1 to T6 and the first and second capacitors C1 and C2 are connected through the first to eighth conductive layers ML1 to ML8. In addition, the drain area corresponding to the drain electrode of the fourth transistor T4, the source area corresponding to the source electrode of the fifth transistor T5, and a first electrode AND of the light emitting element LE are also connected through the first to eighth conductive layers ML1 to ML8.

The first to eighth conductive layers ML1 to ML8 and first to eighth vias VA1 to VA8 may include substantially a same material. The first to eighth conductive layers ML1 to ML8 and the first to eighth vias VA1 to VA8 may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. The first to eighth vias VA1 to VA8 may include substantially the same material. In one or more embodiments, the first to eighth insulating films INS1 to INS8 may each be formed as an inorganic film of silicon oxide (SiOₓ) series, but embodiments of the present disclosure are not limited thereto.

The ninth insulating film INS9 may be arranged on the eighth insulating film INS8 and the eighth conductive layer ML8. In one or more embodiments, the ninth insulating film INS9 may be formed as an inorganic film of silicon oxide (SiOₓ) series, but embodiments of the present disclosure are not limited thereto.

Each of the ninth vias VA9 may be connected to the exposed eighth conductive layer ML8 by penetrating through the ninth insulating film INS9. The ninth vias VA9 may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof.

The display element layer EML may be arranged on the light emitting element backplane EBP. The display element layer EML may include tenth and eleventh insulating films INS10 and INS11, reflective electrodes RL, first electrodes AND, a light emitting stack IL, a second electrode CAT, a pixel defining film PDL, and a plurality of trenches TRC.

The reflective electrodes RL may be arranged on the ninth insulating film INS9. Each of the reflective electrodes RL may include at least one selected from among reflective electrodes RL1, RL2, RL3, and RL4. For example, in one or more embodiments, each of the reflective electrodes RL may include first to fourth reflective electrodes RL1, RL2, RL3, and RL4 as illustrated in FIG. 9.

The first reflective electrodes RL1 may be arranged on the ninth insulating film INS9 and may be connected to the ninth via VA9. Each of second reflective electrodes RL2 may be arranged on the first reflective electrode RL1 corresponding thereto. Each of third reflective electrodes RL3 may be arranged on the second reflective electrode RL2 corresponding thereto. Each of fourth reflective electrodes RL4 may be arranged on the third reflective electrode RL3 corresponding thereto.

Because the second reflective electrode RL2 may be an electrode that substantially reflects light from the light emitting elements, a thickness of the second reflective electrode RL2 may be greater than a thickness of the first reflective electrode RL1, a thickness of the third reflective electrode RL3, and a thickness of the fourth reflective electrode RL4.

The first reflective electrodes RL1 may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. For example, in one or more embodiments, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be arranged on the ninth interlayer insulating film INS9. The tenth interlayer insulating film INS10 may be arranged between the reflective electrodes RL adjacent to each other. The tenth interlayer insulating film INS10 may be a film for planarizing a step difference caused by the reflective electrodes RL. The eleventh interlayer insulating film INS11 may be arranged on the tenth interlayer insulating film INS10 and the reflective electrodes RL.

In one or more embodiments, the tenth interlayer insulating film INS10 and the eleventh interlayer insulating film INS11 may each be formed as an inorganic film of silicon oxide (SiOₓ)-series, but embodiments of the present disclosure are not limited thereto.

The eleventh interlayer insulating film INS11 may be an optical auxiliary layer for adjusting a resonance distance of light emitted from the light emitting stack IL in at least one sub-pixel of the first sub-pixel SP1, the second sub-pixel SP2, or the third sub-pixel SP3. A thickness of the eleventh interlayer insulating film INS11 in each of the first sub-pixel SP1, the second sub-pixel SP2, and the third sub-pixel SP3 may be different. For example, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, in one or more embodiments, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this regard, a distance between the first electrode AND and the reflective electrode RL in the first sub-pixel SP1 may be greater than a distance between the first electrode AND and the reflective electrode RL in the second sub-pixel SP2. In addition, the distance between the first electrode AND and the reflective electrode RL in the second sub-pixel SP2 may be greater than a distance between the first electrode AND and the reflective electrode RL in the third sub-pixel SP3.

Each of the tenth vias VA10 may be connected to the exposed corresponding fourth reflective electrode RL4 by penetrating through the eleventh interlayer insulating film INS11. The tenth vias VA10 may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. A thickness of the tenth via VA10 in the first sub-pixel SP1 may be greater than a thickness of the tenth via VA10 in the second sub-pixel SP2, and the thickness of the tenth via VA10 in the second sub-pixel SP2 may be greater than a thickness of the tenth via VA10 in the third sub-pixel SP3.

The first electrode AND of each of the light emitting elements LE may be arranged on the eleventh interlayer insulating film INS11 and may be connected to the tenth via VA10. The first electrode AND of each of the light emitting elements LE may be connected to the drain area DA or the source area SA of a corresponding pixel transistor PTR through the tenth via VA10, the reflective electrode RL, the first to ninth vias VA1 to VA9, the first to eighth conductive layers ML1 to ML8, and the contact terminal CTE. The first electrode AND of each of the light emitting elements LE may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. For example, in one or more embodiments, the first electrode AND of each of the light emitting elements LE may include titanium nitride (TiN).

The pixel defining film PDL may be arranged on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3. Each of the first light emitting area EA1, the second light emitting area EA2, and the third light emitting area EA3 may be an area in which the light emitting element LE including the first electrode AND, the light emitting stack IL, and the second electrode CAT is arranged.

The first light emitting area EA1 may be defined as an area in which the first electrode AND, the light emitting stack IL, and the second electrode CAT are sequentially stacked in the first sub-pixel SP1 to emit light. The second light emitting area EA2 may be defined as an area in which the first electrode AND, the light emitting stack IL, and the second electrode CAT are sequentially stacked in the second sub-pixel SP2 to emit light. The third light emitting area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of each first electrode AND, the second pixel defining film PDL2 may be arranged on the first pixel defining film PDL1, and the third pixel defining film PDL3 may be arranged on the second pixel defining film PDL2. In one or more embodiments, the first pixel defining film PDL1, the second pixel defining film PDL2, and the third pixel defining film PDL3 may each be formed as an inorganic film of silicon oxide (SiOₓ) series. In one or more embodiments, the first pixel defining film PDL1 and the third pixel defining film PDL3 are each formed as an inorganic film of silicon nitride (SiNₓ) series, while the second pixel defining film PDL2 may be formed as an inorganic film of silicon oxide (SiOₓ) series. Each of a thickness of the first pixel defining film PDL1, a thickness of the second pixel defining film PDL2, and a thickness of the third pixel defining film PDL3 may be approximately 500 angstroms (Å).

In order to prevent or reduce a first encapsulation inorganic film TFE1 from being disconnected due to the step coverage, the first pixel defining film PDL1, the second pixel defining film PDL2, and the third pixel defining film PDL3 may have a cross-sectional structure with a step difference of a step shape (e.g., in a form of staircase). The step coverage refers to a ratio of the extent to which a thin film is applied to an inclined portion relative to the extent to which a thin film is applied to a flat portion. As the step coverage is low, the possibility of the thin film disconnected at the inclined portion may increase.

Each of the plurality of trenches TRC may penetrate through the first pixel defining film PDL1, the second pixel defining film PDL2, and the third pixel defining film PDL3. In one or more embodiments, in each of the plurality of trenches TRC, at least a portion of the eleventh interlayer insulating film INS11 may have a recessed shape.

At least one trench TRC may be arranged between the sub-pixels SP1, SP2, and SP3 adjacent to each other. It is illustrated in FIG. 9 that two trenches TRC are arranged between the sub-pixels SP1, SP2, and SP3 adjacent to each other, but embodiments of the present disclosure are not limited thereto.

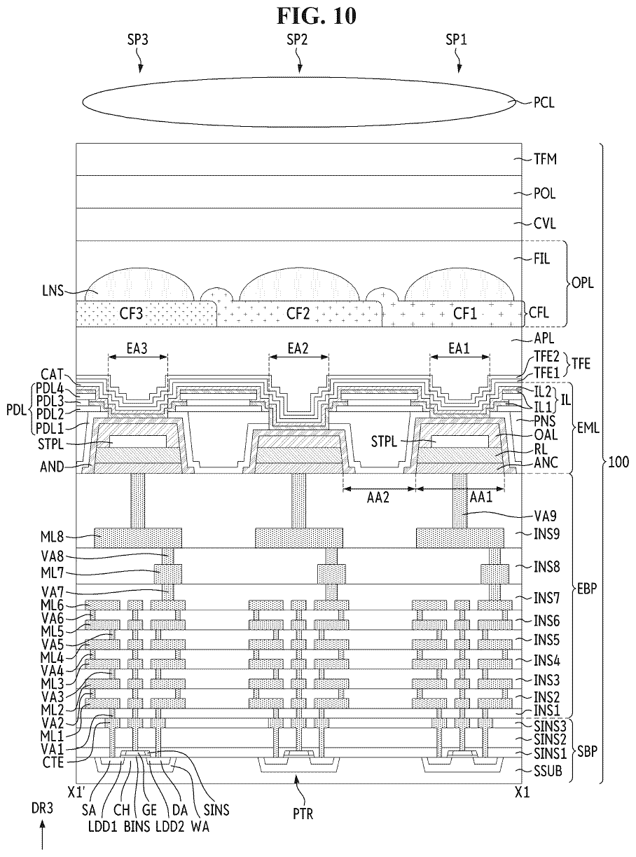

The light emitting stack IL may include a plurality of stack layers IL1, IL2, and IL3. It is illustrated in FIG. 9 that the light emitting stack IL has a three-tandem structure including a first stack layer IL1, a second stack layer IL2, and a third stack layer IL3, but embodiments of present disclosure are not limited thereto. For example, in one or more embodiments, the light emitting stack IL may have a two-tandem structure including two stack layers as illustrated in FIG. 10.

In the three-tandem structure, in one or more embodiments, the light emitting stack IL may have a tandem structure including a plurality of stack layers IL1, IL2, and IL3 that emit different lights. For example, in one or more embodiments, the light emitting stack IL may include a first stack layer IL1 that is configured to emit light of a first color, a second stack layer IL2 that is configured to emit light of a second color, and a third stack layer IL3 that is configured to emit light of a third color. The first stack layer IL1, the second stack layer IL2, and the third stack layer IL3 may be sequentially stacked (e.g., in the stated order).

The first stack layer IL1 may have a structure in which a first hole transporting layer, a first light emitting layer emitting first light, and a first electron transporting layer are sequentially stacked (e.g., in the stated order). The second stack layer IL2 may have a structure in which a second hole transporting layer, a second light emitting layer emitting second light, and a second electron transporting layer are sequentially stacked (e.g., in the stated order). The third stack layer IL3 may have a structure in which a third hole transporting layer, a third organic light emitting layer emitting third light, and a third electron transporting layer are sequentially stacked (e.g., in the stated order).

In one or more embodiments, a first charge generation layer for supplying charges (e.g., holes) to the second stack layer IL2 and supplying electrons to the first stack layer IL1 may be arranged between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generating layer may include a dopant of a metallic material.

A second charge generation layer for supplying charges (e.g., holes) to the third stack layer IL3 and supplying electrons to the second stack layer IL2 may be arranged between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be arranged on the first electrodes AND and the pixel defining film PDL, and in each of the trenches TRC, a residual film RIL arranged on a bottom surface of the trench TRC may be a same material as the first stack layer IL1. Due to the trench TRC, the first stack layer IL1 may be disconnected between the sub-pixels SP1, SP2, and SP3 adjacent to each other. The second stack layer IL2 may be arranged on the first stack layer IL1. Due to the trench TRC, the second stack layer IL2 may be disconnected between the sub-pixels SP1, SP2, and SP3 adjacent to each other. A cavity ESS or empty space may be arranged between the residual film and the second stack layer IL2 in the trench TRC. The third stack layer IL3 may be arranged on the second stack layer IL2. The third stack layer IL3 may not be disconnected by the trench TRC and may be arranged to cover the second stack layer IL2 in each of the trenches TRC.

In the three-tandem structure, each of the plurality of trenches TRC may be a structure for disconnecting the first to third hole transporting layers, the first charge generation layer, and the second charge generation layer of the first to third stack layers IL1, IL2, and IL3 of the display element layer EML between the sub-pixels SP1, SP2, and SP3 adjacent to each other. In addition, in the two-tandem structure, each of the plurality of trenches TRC may be a structure for disconnecting a charge generation layer arranged between a lower stack layer and an upper stack layer and the lower stack layer.

In order to stably disconnect the first and second stack layers IL1 and IL2 of the display element layer EML between the sub-pixels SP1, SP2, and SP3 adjacent to each other, a height of each of the plurality of trenches TRC may be greater than a height of the pixel defining film PDL. The height of each of the plurality of trenches TRC indicates a length of each of the plurality of trenches TRC in the third direction DR3. The height of the pixel defining film PDL indicates a length of the pixel defining film PDL in the third direction DR3. In order to disconnect the hole transporting layers and the charge generation layers of the light emitting stack IL of the display element layer EML between the sub-pixels SP1, SP2, and SP3 adjacent to each other, other structures may be present instead of the trench TRC. For example, in one or more embodiments, instead of the trench TRC, a partition wall having a reverse tapered shape may be arranged on the pixel defining film PDL.

In addition, it is illustrated in FIG. 9 that the light emitting stack IL that emits light is arranged in all of the first light emitting area EA1, the second light emitting area EA2, and the third light emitting area EA3, but embodiments of the present disclosure are not limited thereto. For example, in one or more embodiments, instead of the light emitting stack IL, the first stack layer IL1 may be arranged in the first light emitting area EA1 and may not be arranged in the second light emitting area EA2 and the third light emitting area EA3. In addition, the second stack layer IL2 may be arranged in the second light emitting area EA2 and may not be arranged in the first light emitting area EA1 and the third light emitting area EA3. In addition, the third stack layer IL3 may be arranged in the third light emitting area EA3 and may not be arranged in the first light emitting area EA1 and the second light emitting area EA2. In these embodiments, first to third color filters CF1, CF2, and CF3 of the optical layer OPL may not be provided.

The second electrode CAT may be arranged on the light emitting stack IL. The second electrode CAT may be arranged on the third stack layer IL3 in each of the plurality of trenches TRC. In one or more embodiments, the second electrode CAT may include a transparent conductive material (TCO) such as ITO or IZO capable of transmitting light, or a semi-transmissive conductive material such as magnesium (Mg), silver (Ag), or an alloy of magnesium (Mg) and silver (Ag). When the second electrode CAT includes a semi-transmissive conductive material, light emission efficiency may be increased in each of the first to third sub-pixels SP1, SP2, and SP3 due to a micro cavity effect.

The encapsulation layer TFE may be arranged on the display element layer EML. The encapsulation layer TFE may include one or more of inorganic films TFE1 and TFE2 to prevent or reduce oxygen and/or moisture from permeating into the display element layer EML. For example, a first encapsulation inorganic film TFE1 may be arranged on the second electrode CAT, and a second encapsulation inorganic film TFE2 may be arranged on the first encapsulation inorganic film TFE1. The first encapsulation inorganic film TFE1 and the second encapsulation inorganic film TFE2 may each independently be formed as multi-films in which one or more inorganic films of a silicon nitride layer (SiNₓ), a silicon oxynitride layer (SiON), a silicon oxide layer (SiOₓ), a titanium oxide layer (TiOₓ), and an aluminum oxide layer (AlOₓ) are alternately stacked.

An adhesive layer APL may be a layer for adhering the encapsulation layer TFE and the optical layer OPL. The adhesive layer APL may be a double-sided adhesive member. In addition, the adhesive layer APL may be a transparent adhesive member such as a transparent adhesive or a transparent adhesive resin.

The optical layer OPL includes a plurality of color filters CF1, CF2, and CF3, a polarizing member POL, a plurality of lenses LNS, and a filling layer FIL. The plurality of color filters CF1, CF2, and CF3 may include first to third color filters CF1, CF2, and CF3. The first to third color filters CF1, CF2, and CF3 may be arranged on the adhesive layer APL.

The first color filter CF1 may overlap the first light emitting area EA1 of the first sub-pixel SP1. The first color filter CF1 may be to transmit light of a first color, that is, light in a blue wavelength band. The blue wavelength band may be approximately about 370 nm to about 460 nm. Therefore, the first color filter CF1 may be to transmit light of the first color among light emitted from the first light emitting area EA1.

The second color filter CF2 may overlap the second light emitting area EA2 of the second sub-pixel SP2. The second color filter CF2 may be to transmit light of a second color, that is, light in a green wavelength band. The green wavelength band may be approximately about 480 nm to about 560 nm. Therefore, the second color filter CF2 may be to transmit light of the second color among light emitted from the second light emitting area EA2.

The third color filter CF3 may overlap the third light emitting area EA3 of the third sub-pixel SP3. The third color filter CF3 may be to transmit light of a third color, that is, light in a red wavelength band. The red wavelength band may be approximately about 600 nm to about 750 nm. Therefore, the third color filter CF3 may be to transmit light of the third color among light emitted from the third light emitting area EA3.

The polarizing member POL may be arranged on a (e.g., one) surface of the color filter layer CFL. The polarizing member POL may be a structure for preventing or reducing deterioration in visibility due to reflection of external light. The polarizing member POL may include a linear polarizer and a phase delay layer. However, if (e.g., when) deterioration in visibility due to reflection of external light is sufficiently improved by the first to third color filters CF1, CF2, and CF3, the polarizing member POL may also not be provided.

The linear polarizer may be to emit light emitted from inside the display panel or light incident from outside the display panel as linearly polarized light vibrating in one direction. The linear polarizer may be a reflective linear polarizer or an absorptive linear polarizer. For example, the reflective linear polarizer may be a wire grid polarizer, in this regard, it may be arranged on one surface of the color filter layer CFL. The absorptive polarizer may be a film-type (kind) polarizer, in this regard, the polarizing member POL may be arranged on one surface of the cover layer CVL.

The phase delay layer may delay a phase of incident light. For example, the phase delay layer may be arranged below the linear polarizer to delay a phase of incident linearly polarized light or circularly polarized light. In one or more embodiments, the phase delay layer may be a λ/4 (quarter-wave) plate, but embodiments of the present disclosure are not limited thereto.

Each of the plurality of lenses LNS may be arranged on a corresponding one selected from among the first color filter CF1, the second color filter CF2, and the third color filter CF3. Each of the plurality of lenses LNS may be a structure for increasing a ratio of light directed to the front of the display device 10. In one or more embodiments, each of the plurality of lenses LNS may have a cross-sectional shape that is convex in an upward direction.

The filling layer FIL may be arranged on the plurality of lenses LNS. The filling layer FIL may have a refractive index such that light travels in the third direction DR3 at an interface between the plurality of lenses LNS and the filling layer FIL. In addition, the filling layer FIL may also be a planarization layer. The filling layer FIL may be an organic film made of an acryl resin, an epoxy resin, a phenolic resin, a polyamide resin, a polyimide resin, and/or the like.

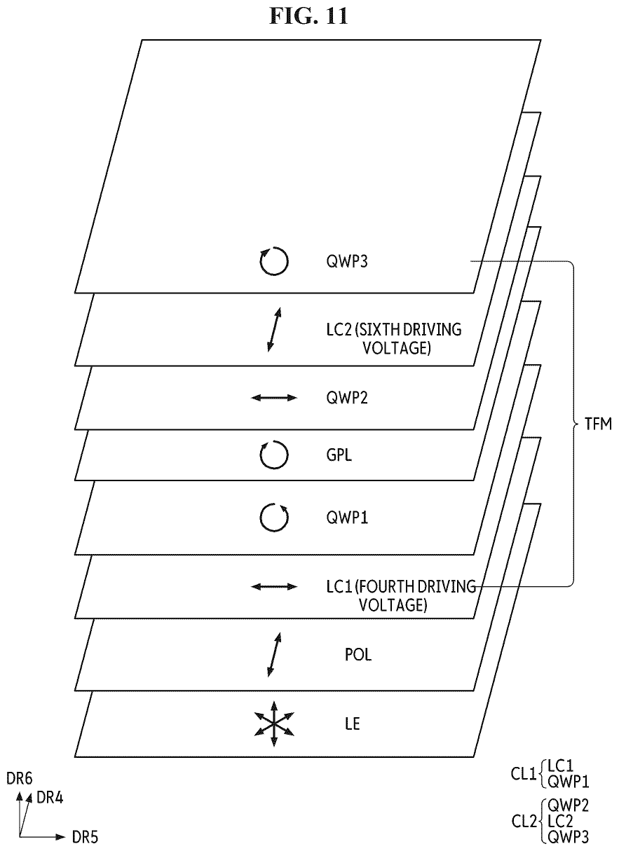

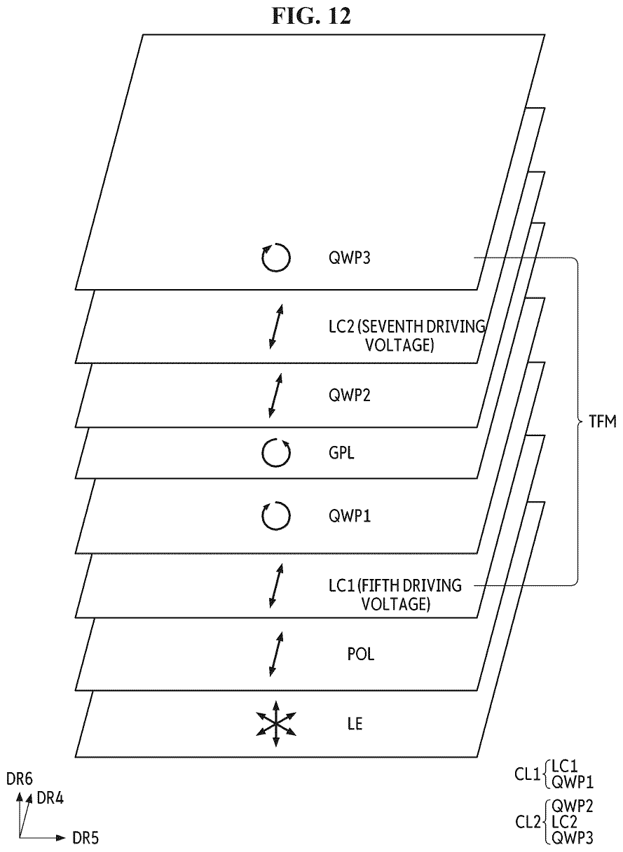

The variable focus module TFM may be arranged on the filling layer FIL. The variable focus module TFM may be arranged on the filling layer FIL so as to overlap all pixels PX including sub-pixels SP1, SP2, and SP3. In one or more embodiments, the variable focus module TFM may be arranged on the filling layer FIL so as to overlap the display area DAA of the display panel 100. The variable focus module TFM may control a focal length. The variable focus module TFM will be described in more detail later with reference to FIG. 11 and FIG. 12.

The cover layer CVL may be arranged on the variable focus module TFM. FIG. 9 illustrates embodiments in which the cover layer CVL is arranged on the variable focus module TFM, but the variable focus module TFM may also be arranged on the cover layer CVL. The cover layer CVL may be a glass substrate or a polymer resin such as resin. In one or more embodiments, when the cover layer CVL is a glass substrate, the cover layer CVL may be attached onto the filling layer FIL. In these embodiments, the filling layer FIL may serve to attach the cover layer CVL. When the cover layer CVL is a glass substrate, the cover layer CVL may serve as an encapsulation substrate. In one or more embodiments, when the cover layer CVL is a polymer resin such as resin, the cover layer CVL may be directly applied onto the filling layer FIL.

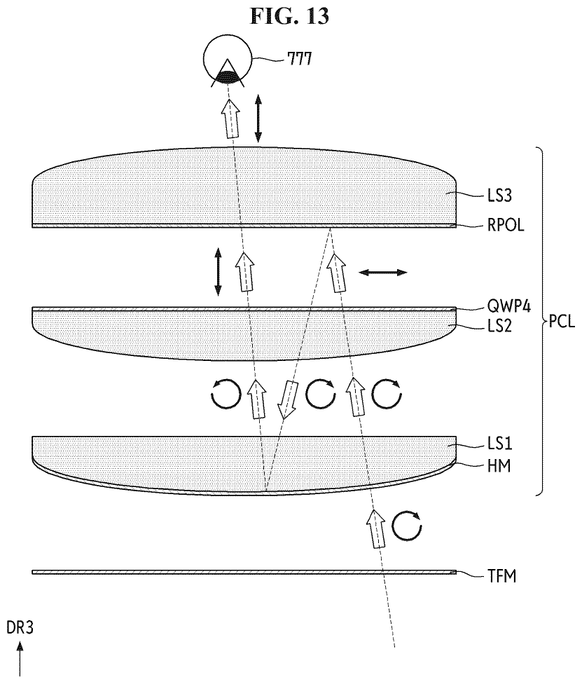

A pancake lens PCL may be arranged on the cover layer CVL. The pancake lens PCL may be spaced and/or apart (e.g., spaced apart or separated) from the cover layer CVL. The pancake lens PCL may provide a wide-angle and large-screen image to a user by refracting or reflecting the light emitted from the display panel. The pancake lens PCL may overlap all pixels PX including sub-pixels SP1, SP2, and SP3. For example, the pancake lens PCL may overlap all the light emitting areas EA1, EA2, and EA3. The pancake lens PCL will be described in more detail later with reference to FIG. 13.

FIG. 10 is a cross-sectional view illustrating another example of the display panel taken along the line X-X1′ of FIG. 7 according to one or more embodiments of the present disclosure.

An embodiment of FIG. 10 differs from the embodiment of FIG. 9 in that the first electrode AND of each of the light emitting elements LE is electrically connected by being in contact with a side surface of a connection electrode ANC connected to the eighth conductive layer ML8. In addition, the embodiment of FIG. 10 differs from the embodiment of FIG. 9 in that the trench TRC is not provided, and instead, a third pixel defining film PDL3 and a fourth pixel defining film PDL4 that have a cross-sectional structure in a shape of an eaves or a mushroom shape are provided. In addition, the embodiment of FIG. 10 differs from the embodiment of FIG. 9 in that the polarizing member POL is arranged on the cover layer CVL, and the variable focus module TFM is arranged on the polarizing member POL. In describing one or more embodiments of FIG. 10, redundant description of parts already described in one or more embodiments of FIG. 9 will not be provided.

Referring to FIG. 10, in one or more embodiments, a plurality of connection electrodes ANC may be respectively arranged on first portions AA1 of the ninth insulating film INS9. Each of the plurality of connection electrodes ANC may be arranged on the first portion AA1 of the ninth insulating film INS9 corresponding thereto. The plurality of connection electrodes ANC may include an alloy or a compound including any one selected from among copper (Cu), aluminum (Al), tungsten (W), molybdenum (Mo), chromium (Cr), gold (Au), titanium (Ti), nickel (Ni), and neodymium (Nd), or a transparent conductive oxide. For example, in one or more embodiments, the plurality of connection electrodes ANC may include titanium (Ti), titanium nitride (TiN), indium tin oxide (ITO), or indium zinc oxide (IZO), but embodiments of the present disclosure are not limited thereto.

The plurality of reflective electrodes RL may be respectively arranged on the plurality of connection electrodes ANC. Each of the plurality of reflective electrodes RL may be arranged on the connection electrode ANC corresponding thereto. The plurality of reflective electrodes RL may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. For example, in one or more embodiments, each of the plurality of reflective electrodes RL may include aluminum (Al) having high reflectivity.

A plurality of optical auxiliary films OAL may be respectively arranged on the plurality of reflective electrodes RL. Each of plurality of optical auxiliary films OAL may be arranged on the reflective electrode RL corresponding thereto. In one or more embodiments, the plurality of optical auxiliary films OAL may be formed as an inorganic film of silicon oxide (SiOₓ) series, but embodiments of the present disclosure are not limited thereto.

In one or more embodiments, a step layer STPL may be arranged on the reflective electrode RL in each of the first light emitting area EA1 and the third light emitting area EA3, and the optical auxiliary film OAL may be arranged on the step layer STPL. In the second light emitting area EA2, only the optical auxiliary film OAL may be arranged on the reflective electrode RL. The thicknesses of the optical auxiliary film OAL in the first light emitting area EA1, the second light emitting area EA2, and the third light emitting area EA3 may be substantially the same.

Due to the step layer STPL, a distance between the reflective electrode RL and the first electrode AND in each of the first light emitting area EA1 and the third light emitting area EA3 may be greater than a distance between the reflective electrode RL and the first electrode AND in the second light emitting area EA2. The thickness of the step layer STPL and the thickness of the optical auxiliary film OAL may be set by considering the wavelength and resonance distance of light emitted from the first stack layer IL1 of the light emitting stack IL and the wavelength and resonance distance of light emitted from the second stack layer IL2 thereof.

Each of the light emitting elements LE may include a first electrode AND, a light emitting stack IL, and a second electrode CAT.

The first electrode AND of each of the light emitting elements LE may be arranged on the optical auxiliary film OAL corresponding thereto. Because the connection electrode ANC, the reflective electrode RL, and the optical auxiliary film OAL are sequentially stacked, the first electrode AND of each of the light emitting elements LE may be arranged on upper and side surfaces of the optical auxiliary film OAL, a side surface of the reflective electrode RL, and a side surface of the connection electrode ANC. As a result, the first electrode AND of each of the light emitting elements LE may be electrically connected by being in contact with the side surface of the reflective electrode RL and the side surface of the connection electrode ANC. Therefore, because the mask process may be reduced compared to if (e.g., when) the first electrode AND of each of the light emitting elements LE is connected to the exposed reflective electrode RL through a through hole penetrating through the optical auxiliary film OAL, manufacturing costs may be reduced and manufacturing efficiency may be increased.

The first electrode AND of each of the light emitting elements LE may be connected to the drain area DA or the source area SA of a corresponding pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. In one or more embodiments, a thickness of the first portion AA1 and a thickness of the second portion AA2 of the ninth insulating film INS9 may be substantially the same.

In one or more embodiments, the thickness of the first portion AA1 of the ninth insulating film INS9 may be greater than the thickness of the second portion AA2. In this regard, a side surface of the first portion AA1 of the ninth insulating film INS9 may be exposed, and the first electrode AND of each of the light emitting elements LE may be arranged on the exposed side surface of the first portion AA1 of the ninth insulating film INS9.

The first electrode AND of each of the light emitting elements LE may include any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof, or a transparent conductive oxide. For example, in one or more embodiments, the first electrode AND of each of light emitting elements LE may include titanium nitride (TiN), indium tin oxide (ITO), or indium zinc oxide (IZO), but embodiments of the present disclosure are not limited thereto.

The pixel defining film PDL may be arranged on a partial area of the first electrode AND of each of the light emitting elements LE. The pixel defining film PDL may cover an edge of the first electrode AND of each of the light emitting elements LE. The pixel defining film PDL may partition the first light emitting areas EA1, the second light emitting areas EA2, and the third light emitting areas EA3.

The pixel defining film PDL may include first to fourth pixel defining films PDL1, PDL2, PDL3, and PDL4.

The first pixel defining film PDL1 may be arranged on the first electrode AND of each of the light emitting elements LE. For example, the first pixel defining film PDL1 may cover a portion of an upper surface of the first electrode AND arranged on the optical auxiliary film OAL. In addition, the first pixel defining film PDL1 may cover the first electrode AND arranged on the side surface of the connection electrode ANC, the side surface of the reflective electrode RL, and the side surface of the optical auxiliary film OAL. The first pixel defining film PDL1 may be arranged on an upper surface of the second portion AA2 of the ninth insulating film INS9.

A planarization film PNS is a film for planarizing the step differences or surface irregularities caused by the connection electrode ANC, the reflective electrode RL, and the optical auxiliary film OAL.

The planarization film PNS may be arranged on the first pixel defining film PDL1 that covers the first electrode AND arranged on the side surface of the connection electrode ANC, the side surface of the reflective electrode RL, and the side surface of the optical auxiliary film OAL. The planarization film PNS may be arranged on the first pixel defining film PDL1 arranged on the second portion AA2 of the ninth insulating film INS9.

The planarization film PNS may be arranged between the connection electrodes ANC adjacent to each other in the first direction DR1 or the second direction DR2. The planarization film PNS may be arranged between the reflective electrodes RL adjacent to each other in the first direction DR1 or the second direction DR2. The planarization film PNS may be arranged between the optical auxiliary films OAL adjacent to each other in the first direction DR1 or the second direction DR2.

While there is no step layer STPL in the second light emitting area EA2, there is a step layer STPL in each of the first light emitting area EA1 and the third light emitting area EA3. As a result, the height of the connection electrode ANC, the reflective electrode RL, and the optical auxiliary film OAL in the second light emitting area EA2 may be smaller than the height of the connection electrode ANC, the reflective electrode RL, the step layer STPL, and the optical auxiliary film OAL in each of the first light emitting area EA1 and the third light emitting area EA3. Therefore, the planarization film PNS may cover an upper surface of the first pixel defining film PDL1 arranged on the upper surface of the first electrode AND arranged in the second light emitting area EA2.

In comparison, an upper surface of the planarization film PNS may be flatly connected to the upper surface of the first electrode AND arranged in each of the first light emitting area EA1 and the third light emitting area EA3. For example, the planarization film PNS may not cover the upper surface of the first pixel defining film PDL1 arranged on the upper surface of the first electrode AND arranged in each of the first light emitting area EA1 and the third light emitting area EA3.

The second pixel defining film PDL2 may be arranged on the first pixel defining film PDL1 and the planarization film PNS, the third pixel defining film PDL3 may be arranged on the second pixel defining film PDL2, and the fourth pixel defining film PDL4 may be arranged on the third pixel defining film PDL3. In one or more embodiments, the first pixel defining film PDL1 and the third pixel defining film PDL3 are each formed as an inorganic film of silicon nitride (SiNₓ), while the second pixel defining film PDL2, the fourth pixel defining film PDL4, and the planarization film PNS may each be formed as an inorganic film of silicon oxide (SiOₓ). As the first pixel defining film PDL1 is formed of a different material from the planarization film PNS, the first pixel defining film PDL1 may serve as a stopper in a process of chemically and mechanically polishing the planarization film PNS.

When the planarization film PNS and the second pixel defining film PDL2 are identically formed as an inorganic film of silicon oxide (SiOₓ), the planarization film PNS and the second pixel defining film PDL2 may be formed as a single film.

Because a length of the third pixel defining film PDL3 in one direction is smaller than a length of the fourth pixel defining film PDL4 in the one direction, a lower surface of the fourth pixel defining film PDL4 may be exposed without being covered by the third pixel defining film PDL3. For example, the third pixel defining film PDL3 and the fourth pixel defining film PDL4 may have a cross-sectional structure in a shape of an eaves or a mushroom shape.

The light emitting stack IL may be arranged on the first electrodes AND and the pixel defining film PDL. The light emitting stack IL may include a first stack layer IL1 and a second stack layer IL2 that emit different lights. When the light emitting stack IL has a two-tandem structure, any one selected from among the first stack layer IL1 and the second stack layer IL2 may be to emit light including a wavelength range of any one selected from among the first light, the second light, and the third light, and the remaining one may be to emit light that includes the wavelength ranges of the other two lights. For example, in one or more embodiments, the first stack layer IL1 may be to emit light that includes a wavelength range of the first light and a wavelength range of the third light, and the second stack layer IL2 may be to emit light that includes a wavelength range of the second light. Here, the first light may be light in a blue wavelength band, the second light may be light in a green wavelength band, and the third light may be light in a red wavelength band.

A charge generation layer for supplying charges (e.g., charge carries or holes) to the second stack layer IL2 and supplying electrons to the first stack layer IL1 may be arranged between the first stack layer IL1 and the second stack layer IL2. The charge generation layer may include an N-type (kind) charge generation layer that supplies electrons to the first stack layer IL1 and a P-type (kind) charge generation layer that supplies holes to the second stack layer IL2. The N-type (kind) charge generating layer may include a dopant of a metallic material.

Because the first stack layer IL1 is not formed on the exposed lower surface of the fourth pixel defining film PDL4 that is not covered by the third pixel defining film PDL3, the first stack layer IL1 may be disconnected by the cross-sectional structure in the shape of an eaves or the mushroom shape by the third pixel defining film PDL3 and the fourth pixel defining film PDL4. In this regard, the first hole transporting layer of the first stack layer IL1 and the charge generation layer arranged between the first stack layer IL1 and the second stack layer IL2 may also be disconnected. In addition, it is illustrated in FIG. 10 that the second stack layer IL2 is connected without being disconnected, but the second hole transporting layer of the second stack layer IL2 may be disconnected, and the second electron transporting layer of the second stack layer IL2 may be connected without being disconnected. Therefore, it may prevent or reduce leakage current from flowing between the light emitting areas EA1, EA2, and EA3 adjacent to each other through the first hole transporting layer of the first stack layer IL1, the second hole transporting layer of the second stack layer IL2, and the charge generation layer. Therefore, it may prevent or reduce the light emitting stacks IL in the light emitting areas EA1, EA2, and EA3 adjacent to each other from being affected by the leakage current and emitting light other than the originally intended light.

FIG. 10 illustrates the two-tandem structure in which the light emitting stack IL includes two stack layers IL1 and IL2, but embodiments of the present disclosure are not limited thereto. For example, in one or more embodiments, the light emitting stack IL may have a three-tandem structure including three stack layers as illustrated in FIG. 9. In these embodiments, by adjusting the height of the third pixel defining film PDL3, the charge generation layer between the first stack layer IL1 and the second stack layer IL2, and the charge generation layer between the second stack layer IL2 and the third stack layer IL3 may be designed to be disconnected. In one or more embodiments, as illustrated in FIG. 9, a trench penetrating through the first pixel defining film PDL1, planarization film PNS, the second pixel defining film PDL2, and the third pixel defining film PDL3 may be added. In this regard, the trench TRC may penetrate through at least a portion of the ninth insulating film INS9, but embodiments of the present disclosure are not limited thereto.

FIG. 11 is a view for describing a detailed structure of a variable focus module TFM, and a polarization direction and travel path of light in a light emitting element, a polarizing member, and the variable focus module TFM of the display panel if (e.g., when) a fourth driving voltage and a sixth driving voltage are applied to a first polarization conversion layer LC1 and a second polarization conversion layer LC2, respectively, according to one or more embodiments of the present disclosure.

FIG. 12 is a view for describing a detailed structure of a variable focus module TFM, and a polarization direction and travel path of light in a light emitting element, a polarizing member, and the variable focus module TFM of the display panel if (e.g., when) a fifth driving voltage and a seventh driving voltage are applied to a first polarization conversion layer LC1 and a second polarization conversion layer LC2, respectively, according to one or more embodiments of the present disclosure.

Referring to FIG. 11 and FIG. 12, the variable focus module TFM may include a first polarization control layer CL1, a geometric phase lens GPL, and a second polarization control layer CL2.

The first polarization control layer CL1 is a layer that emits incident light as first circularly polarized light or second circularly polarized light. The first polarization control layer CL1 may include a first polarization conversion layer LC1 and a first phase delay layer QWP1.

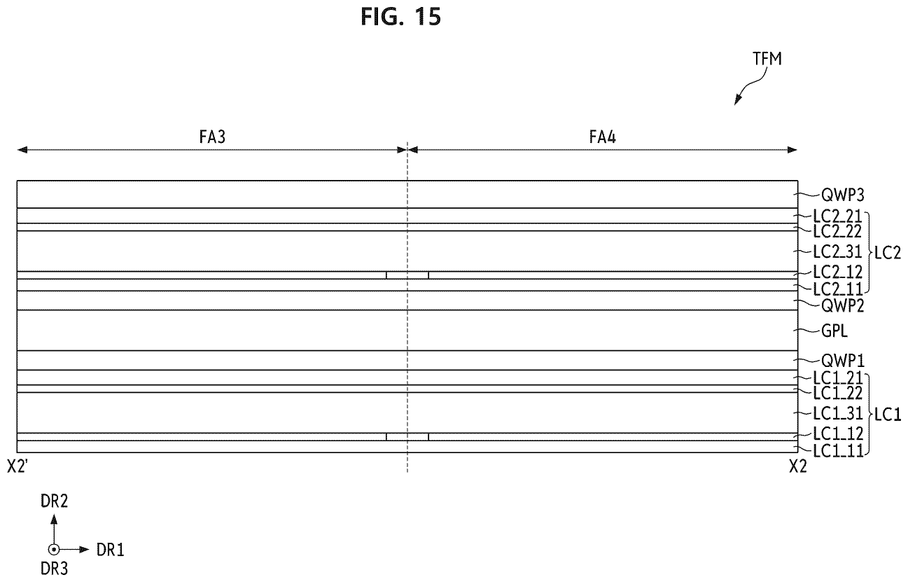

The first polarization conversion layer LC1 may be arranged on the filling layer FIL or the polarizing member POL of the display panel 100. The first polarization conversion layer LC1 may be formed of a liquid crystal panel including a twisted nematic liquid crystal. The first polarization conversion layer LC1 may output a first linearly polarized light incident on the first polarization conversion layer LC1 as it is or convert the first linearly polarized light into a second linearly polarized light and output the second linearly polarized light, depending on the application of a fourth driving voltage or a fifth driving voltage. The fourth driving voltage and the fifth driving voltage may include a first pixel voltage applied to a first pixel electrode (LC1_12 in FIG. 15) of the first polarization conversion layer LC1 and a first common voltage applied to a first common electrode (LC1_22 in FIG. 15). The fourth driving voltage may have a difference between the first pixel voltage and the first common voltage, which is a threshold voltage or less. In this case, the first linearly polarized light incident on the first polarization conversion layer LC1 may be converted into the second linearly polarized light and emitted. The fifth driving voltage may have a difference between the first pixel voltage and the first common voltage, which is a threshold voltage or more. In this case, the first linearly polarized light incident on the first polarization conversion layer LC1 may be emitted as it is.

The first linearly polarized light may have an optical axis in a fourth direction DR4. The second linearly polarized light may have an optical axis in a fifth direction DR5 orthogonal to the fourth direction DR4. For example, the first linearly polarized light may be light vibrating in the fourth direction DR4, and the second linearly polarized light may be light vibrating in the fifth direction DR5. Here, the fourth direction DR4 may be a direction parallel to one side (e.g., a long side) of the first polarization conversion layer LC1, and the fifth direction DR5 may be a direction parallel to the other side (e.g., a short side) orthogonal to the one side of the first polarization conversion layer LC1.

The structure of the first polarization conversion layer LC1 will be described in more detail later with reference to FIG. 15.

The first phase delay layer QWP1 may be arranged on the first polarization conversion layer LC1. The first phase delay layer QWP1 may delay a phase of incident light by a wavelength. For example, in one or more embodiments, the first phase delay layer QWP1 may be a λ/4 (quarter-wave) plate, but embodiments of the present disclosure are not limited thereto. The first phase delay layer QWP1 may delay the phase of the first linearly polarized light or the second linearly polarized light incident from the first polarization conversion layer LC1. The first phase delay layer QWP1 may convert the first linearly polarized light into first circularly polarized light (or first elliptically polarized light), which is counterclockwise. The first phase delay layer QWP1 may convert the second linearly polarized light into second circularly polarized light (or second elliptically polarized light), which is clockwise.

The geometric phase lens GPL may be arranged on the first phase delay layer QWP1. The geometric phase lens GPL is an optical element that controls a path of light depending on a change in a state of circularly or elliptically polarized light. For example, in one or more embodiments, the geometric phase lens GPL may be a Pancharatnam-Berry Phase (PBP) lens. The geometric phase lens GPL may have a structure including a photo-alignment film and liquid crystals aligned by the photo-alignment film between substrates. In this regard, the aligned liquid crystals may have the characteristics of a phase delay of λ/2. When circularly polarized light or elliptically polarized light, such as the first circularly polarized light (or the first elliptically polarized light) or the second circularly polarized light (or the second elliptically polarized light), is incident on the geometric phase lens GPL, the polarization state of light continuously changes. Therefore, the circularly polarized light or the elliptically polarized light may cause a phase difference by the liquid crystal of the geometric phase lens GPL, and a direction of propagation of light may be adjusted by the phase difference. As a result, the geometric phase lens GPL may form a plurality of focal positions.

Therefore, the geometric phase lens GPL may adjust a focal length depending on the direction of the circularly polarized light incident from the first phase delay layer QWP1. When the first circularly polarized light emitted from the first phase delay layer QWP1 is incident on the geometric phase lens GPL, the geometric phase lens GPL may function as a concave lens. For example, if (e.g., when) the first circularly polarized light is incident on the geometric phase lens GPL, the geometric phase lens GPL may have a first focal length. The first focal length may be a focal length of a virtual image. Unlike this, if (e.g., when) the second circularly polarized light emitted from the first phase delay layer QWP1 is incident on the geometric phase lens GPL, the geometric phase lens GPL may function as a convex lens. For example, if (e.g., when) the second circularly polarized light is incident on the geometric phase lens GPL, the geometric phase lens GPL may have a second focal length. The second focal length may be a focal length of a real image.

In addition, because the geometric phase lens GPL has the characteristics of the phase delay of λ/2, the geometric phase lens GPL may be to emit circularly polarized light in a direction opposite to the incident circularly polarized light. For example, if (e.g., when) the first circularly polarized light is incident on the geometric phase lens GPL, the geometric phase lens GPL may be to emit the second circularly polarized light. Conversely, if (e.g., when) the second circularly polarized light is incident on the geometric phase lens GPL, the geometric phase lens GPL may be to emit the first circularly polarized light.

The second polarization control layer CL2 converts the first circularly polarized light or the second circularly polarized light emitted from the geometric phase lens GPL into the second circularly polarized light and outputs the converted second circularly polarized light. The second polarization control layer CL2 may include a second phase delay layer QWP2, a second polarization conversion layer LC2, and a third phase delay layer QWP3.

The second phase delay layer QWP2 may be arranged on the geometric phase lens GPL. The second phase delay layer QWP2 may delay a phase of incident light by a wavelength. For example, in one or more embodiments, the second phase delay layer QWP2 may be a λ/4 (quarter-wave) plate, but embodiments of the present disclosure are not limited thereto. The second phase delay layer QWP2 may delay the phase of the first circularly polarized light or the second circularly polarized light incident from the geometric phase lens GPL. The second phase delay layer QWP2 may convert the first circularly polarized light into the first linearly polarized light. The second phase delay layer QWP2 may convert the second circularly polarized light into the second linearly polarized light.

The second polarization conversion layer LC2 may be arranged on the second phase delay layer QWP2. The second polarization conversion layer LC2 may be formed of a liquid crystal panel including a twisted nematic liquid crystal. The second polarization conversion layer LC2 may output the first linearly polarized light incident on the second polarization conversion layer LC2 as it is or convert the incident second linearly polarized light into the first linearly polarized light and output the first linearly polarized light, depending on the application of a sixth driving voltage or a seventh driving voltage. The sixth driving voltage and the seventh driving voltage may include a second pixel voltage applied to a second pixel electrode (LC2_12 in FIG. 15) of the second polarization conversion layer LC2 and a second common voltage applied to a second common electrode (LC2_22 in FIG. 15). The sixth driving voltage may have a difference between the second pixel voltage and the second common voltage, which is a threshold voltage or less. In this case, the second linearly polarized light incident on the second polarization conversion layer LC2 may be converted into the first linearly polarized light and emitted. The seventh driving voltage may have a difference between the second pixel voltage and the second common voltage, which is a threshold voltage or more. In this case, the first linearly polarized light incident on the second polarization conversion layer LC2 may be emitted as it is.

The structure of the second polarization conversion layer LC2 will be described in more detail later with reference to FIG. 15.

The third phase delay layer QWP3 may be arranged on the second polarization conversion layer LC2. The third phase delay layer QWP3 may delay a phase of incident light by a wavelength. For example, in one or more embodiments, the third phase delay layer QWP3 may be a λ/4 (quarter-wave) plate, but embodiments of the present disclosure are not limited thereto. The third phase delay layer QWP3 may delay the phase of the first linearly polarized light incident from the second polarization conversion layer LC2 and convert the first linearly polarized light into the second circularly polarized light.

Hereinafter, when the fourth driving voltage and the sixth driving voltage are respectively applied to the first polarization conversion layer LC1 and the second polarization conversion layer LC2 of the variable focus module TFM, a polarization direction and travel path of light will be described in more detail with reference to FIG. 11.

The light emitted from the light emitting element LE of the display panel 100 may not have directionality. The light emitted from the light emitting element LE of the display panel 100 may pass through the color filter layer CFL of the display panel 100 and be provided to the polarizing member POL.

The light incident on the polarizing member POL of the display panel 100 may be emitted as first linearly polarized light having an optical axis in the fourth direction DR4 orthogonal to an absorption axis reflected or absorbed by the polarizing member POL. The first linearly polarized light emitted from the polarizing element POL may pass through other components of the display panel 100, such as the color filter layer CFL, the cover layer CVL, and/or the like, and be incident on the first polarization conversion layer LC1 of the variable focus module TFM.

When the fourth driving voltage is applied to the first polarization conversion layer LC1, the first linearly polarized light incident on the first polarization conversion layer LC1 may be converted into second linearly polarized light having an optical axis orthogonal to the first linearly polarized light and be emitted. For example, the second linearly polarized light may have an optical axis in the fifth direction DR5. The second linearly polarized light emitted from the first polarization conversion layer LC1 may be incident on the first phase delay layer QWP1.

The second linearly polarized light incident on the first phase delay layer QWP1 may be phase delayed and emitted as first circularly polarized light. The first circularly polarized light emitted from the first phase delay layer QWP1 may be incident on the geometric phase lens GPL.

The first circularly polarized light incident on the geometric phase lens GPL may be emitted as second circularly polarized light in a direction opposite to the first circularly polarized light. When the first circularly polarized light is incident on the geometric phase lens GPL, the geometric phase lens GPL functions as a concave lens. Therefore, the geometric phase lens GPL may have a focal length of a virtual image. The second circularly polarized light emitted from the geometric phase lens GPL may be incident on the second phase delay layer QWP2.

The second circularly polarized light incident on the second phase delay layer QWP2 may be phase delayed and emitted as the second linearly polarized light. The second linearly polarized light emitted from the second phase delay layer QWP2 may be incident on the second polarization conversion layer LC2.

When the sixth driving voltage is applied to the second polarization conversion layer LC2, the second linearly polarized light incident on the second polarization conversion layer LC2 may be converted into the first linearly polarized light orthogonal to the second linearly polarized light and be emitted. The first linearly polarized light emitted from the second polarization conversion layer LC2 may be incident on the third phase delay layer QWP3.

The first linearly polarized light incident on the third phase delay layer QWP3 may be phase delayed and emitted as the second circularly polarized light. The second circularly polarized light emitted from the third phase delay layer QWP3 may be incident on the pancake lens PCL. The pancake lens PCL will be described in more detail later with reference to FIG. 13.

When the fifth driving voltage and the seventh driving voltage are respectively applied to the first polarization conversion layer LC1 and the second polarization conversion layer LC2 of the variable focus module TFM, a polarization direction and travel path of light will be described in more detail with reference to FIG. 12.

The light emitted from the light emitting element LE of the display panel 100 may not have directionality. The light emitted from the light emitting element LE of the display panel 100 may pass through the color filter layer CFL of the display panel 100 and be provided to the polarizing member POL.

The light incident on the polarizing member POL of the display panel 100 may be emitted as first linearly polarized light having an optical axis in the fourth direction DR4 orthogonal to an absorption axis reflected or absorbed by the polarizing member POL. The first linearly polarized light emitted from the polarizing element POL may pass through other components of the display panel 100 and be incident on the first polarization conversion layer LC1 of the variable focus module TFM.

When the fifth driving voltage is applied to the first polarization conversion layer LC1, the first linearly polarized light incident on the first polarization conversion layer LC1 may be emitted as it is without being converted in the direction. The first linearly polarized light emitted from the first polarization conversion layer LC1 may be incident on the first phase delay layer QWP1.

The first linearly polarized light incident on the first phase delay layer QWP1 may be phase delayed and emitted as second circularly polarized light in a clockwise direction. The second circularly polarized light emitted from the first phase delay layer QWP1 may be incident on the geometric phase lens GPL.

The second circularly polarized light incident on the geometric phase lens GPL may be emitted as first circularly polarized light in a direction opposite to the second circularly polarized light. When the second circularly polarized light is incident on the geometric phase lens GPL, the geometric phase lens GPL functions as a convex lens. Therefore, the geometric phase lens GPL may have a focal length of a real image. The first circularly polarized light emitted from the geometric phase lens GPL may be incident on the second phase delay layer QWP2.

The first circularly polarized light incident on the second phase delay layer QWP2 may be phase delayed and emitted as the first linearly polarized light. The first linearly polarized light emitted from the second phase delay layer QWP2 may be incident on the second polarization conversion layer LC2.

When the seventh driving voltage is applied to the second polarization conversion layer LC2, the first linearly polarized light incident on the second polarization conversion layer LC2 may be emitted as it is without being converted in the direction and be emitted as the first linearly polarized light. The first linearly polarized light emitted from the second polarization conversion layer LC2 may be incident on the third phase delay layer QWP3.

The first linearly polarized light incident on the third phase delay layer QWP3 may be phase delayed and emitted as the second circularly polarized light. The second circularly polarized light emitted from the third phase delay layer QWP3 may be incident on the pancake lens PCL. The pancake lens PCL will be described in more detail later with reference to FIG. 13.

FIG. 13 is a view for describing a detailed structure and a travel path of light of the pancake lens PCL of FIGS. 9 to 12 according to one or more embodiments of the present disclosure.

Referring to FIG. 13, the pancake lens PCL may include a semitransparent mirror HM, a first lens LS1, a second lens LS2, a fourth phase delay layer QWP4, a reflective polarizing layer RPOL, and a third lens LS3.

The semitransparent mirror HM may be spaced and/or apart (e.g., spaced apart or separated) from the variable focus module TFM. The semitransparent mirror HM may be to transmit a portion of the incident light and reflect another portion of the incident light. The semitransparent mirror HM may have a curved shape or a parabolic shape which is convex in a downward direction. The downward direction may be a direction from the pancake lens PCL toward the display panel 100, and an upward direction may be an opposite direction of the downward direction.

The first lens LS1 may be arranged on the semitransparent mirror HM. The first lens LS1 may be a convex lens that is convex in the downward direction. Because the first lens LS1 may have a convex surface and a flat surface opposite to (e.g., facing) each other in the third direction DR3, the semitransparent mirror HM described above may be in contact with the convex surface of the first lens LS1.

The second lens LS2 may be arranged on the first lens LS1. The second lens LS2 may be a convex lens that is convex in the downward direction. The second lens LS2 may have a convex surface and a flat surface opposite to (e.g., facing) each other in the third direction DR3.

The fourth phase delay layer QWP4 may be arranged on the second lens LS2. For example, the fourth phase delay layer QWP4 may be arranged on the flat surface of the second lens LS2. The fourth phase delay layer QWP4 may be in contact with the flat surface of the second lens LS2. The fourth phase delay layer QWP4 may delay a phase of incident light by a wavelength. For example, in one or more embodiments, the fourth phase delay layer QWP4 may be a λ/4 (quarter-wave) plate, but embodiments of the present disclosure are not limited thereto.

The reflective polarizing layer RPOL may be arranged on the fourth phase delay layer QWP4. The reflective polarizing layer RPOL may reflect or transmit the incident linearly polarized light depending on the polarization direction. If (e.g., when) the direction of the incident linearly polarized light is the same as a transmission axis of the reflective polarizing layer RPOL, the incident linearly polarized light may be to transmit through the reflective polarizing layer RPOL, and if (e.g., when) the direction of the incident linearly polarized light is orthogonal to the transmission axis of the reflective polarizing layer RPOL, the incident linearly polarized light may be reflected.

The third lens LS3 may be arranged on the reflective polarizing layer RPOL. The third lens LS3 may be a convex lens that is convex in the upward direction. The third lens LS3 may have a convex surface and a flat surface opposite to (e.g., facing) each other in the third direction DR3. The reflective polarizing layer RPOL described above may be arranged in contact with the flat surface of the third lens LS3.

The second circularly polarized light emitted from the third phase delay layer QWP3 of the variable focus module TFM may be incident on the semitransparent mirror HM of the pancake lens PCL. A portion of the second circularly polarized light incident on the semitransparent mirror HM may be reflected by the semitransparent mirror HM and incident on the variable focus module TFM, and another portion of the second circularly polarized light incident on the semitransparent mirror HM may be refracted by the first lens LS1.

The second circularly polarized light refracted by the first lens LS1 may pass through the second lens LS2 and be incident on the fourth phase delay layer QWP4. The second circularly polarized light incident on the fourth phase delay layer QWP4 may be phase delayed and emitted as the second linearly polarized light. The second linearly polarized light emitted from the fourth phase delay layer QWP4 may be incident on the reflective polarizing layer RPOL.

Because the second linearly polarized light incident on the reflective polarizing layer RPOL has a polarization direction orthogonal to the transmission axis of the reflective polarizing layer RPOL, the second linearly polarized light incident on the reflective polarizing layer RPOL may be reflected by the reflective polarizing layer RPOL.

The second linearly polarized light reflected by the reflective polarizing layer RPOL is incident on the fourth phase delay layer QWP4. The second linearly polarized light incident on the fourth phase delay layer QWP4 may be phase delayed and emitted as the second circularly polarized light.

The second circularly polarized light emitted from the fourth phase delay layer QWP4 may sequentially pass through the second lens LS2 and the first lens LS1 and be incident on the semitransparent mirror HM.

The second circularly polarized light incident on the semitransparent mirror may be reflected by the semitransparent mirror HM and converted into the first circularly polarized light. The first circularly polarized light reflected by the semitransparent mirror HM may sequentially pass through the first lens LS1 and the second lens LS2 and be incident on the fourth phase delay layer QWP4. The first circularly polarized light incident on the fourth phase delay layer QWP4 may be phase delayed and emitted as the first linearly polarized light.

The first linearly polarized light emitted from the fourth phase delay layer QWP4 may be incident on the reflective polarizing layer RPOL. Because the first linearly polarized light is parallel to the transmission axis of the reflective polarizing layer RPOL, the first linearly polarized light may pass through the reflective polarizing layer RPOL.

The first linearly polarized light passing through the reflective polarizing layer RPOL may pass through the third lens LS3 and be incident on the user's eye 777.

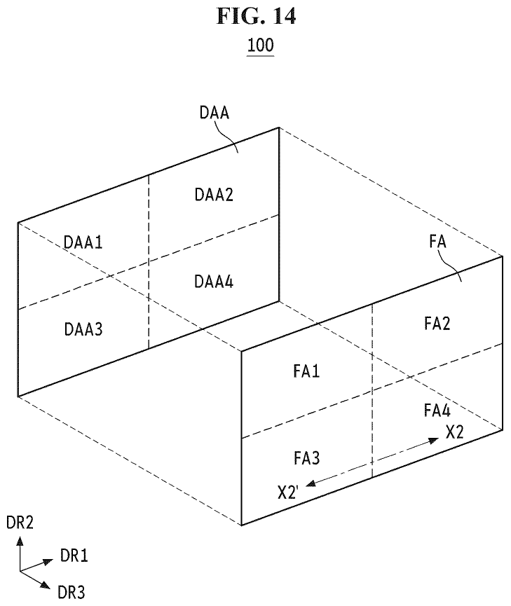

FIG. 14 is a perspective view illustrating a plurality of display areas DAA of a display device and a plurality of variable focus areas FA of a variable focus module according to one or more embodiments of the present disclosure.

Referring to FIG. 14, a display area DAA of the display panel 100 includes a plurality of display areas DAA1, DAA2, DAA3, and DAA4, and a variable focus area FA of the variable focus module TFM of the display panel 100 includes a plurality of variable focus areas FA1, FA2, FA3, and FA4.

Each of the plurality of display areas DAA1, DAA2, DAA3, and DAA4 is an area that includes the plurality of light emitting areas (EA1, EA2, and EA3 in FIG. 7) and emits light. Each of the plurality of variable focus areas FA1, FA2, FA3, and FA4 is an area in which a focal length is adjusted by the variable focus module TFM.

The plurality of display areas DAA1, DAA2, DAA3, and DAA4 and the plurality of variable focus areas FA1, FA2, FA3, and FA4 may correspond to each other in a one-to-one manner. Each of the plurality of display areas DAA1, DAA2, DAA3, and DAA4 may overlap the variable focus area corresponding thereto in the third direction DR3. For example, a first display area DAA1 may overlap a first variable focus area FA1 in the third direction DR3, and a second display area DAA2 may overlap a second variable focus area FA2 in the third direction DR3. In addition, a third display area DAA3 may overlap a third variable focus area FA3 in the third direction DR3, and a fourth display area DAA4 may overlap a fourth variable focus area FA4 in the third direction DR3.

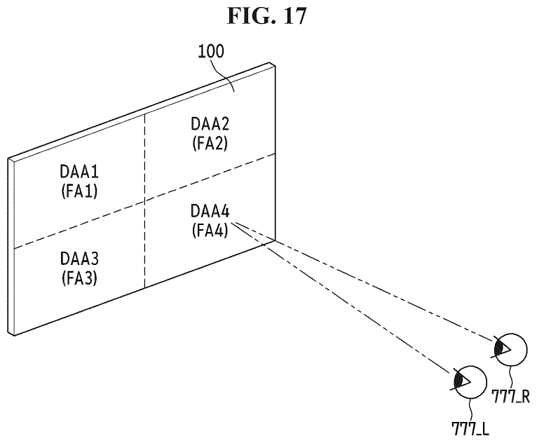

For example, as illustrated in FIG. 17, if (e.g., when) the user gazes at the fourth display area DAA4 among the plurality of display areas DAA1, DAA2, DAA3, and DAA4, a focal length in the fourth variable focus area FA4 corresponding to the fourth display area DAA4 may be varied depending on a depth of the user's gaze towards the fourth display area (DAA4), i.e., a focal length of the user's eyes. For example, it may reduce or prevent an occurrence of fatigue in the user's eyes due to the mismatch in focus when viewing the near and far objects in a virtual reality image by varying a focal length in a corresponding variable focus area of the variable focus module TFM, depending on whether the user gazes at a near or far distance in the display area.

FIG. 15 is a cross-sectional view illustrating an example of the variable focus module taken along the line X2-X2′ of FIG. 14 according to one or more embodiments of the present disclosure.

Referring to FIG. 15, the variable focus module TFM may include a first polarization conversion layer LC1, a first phase delay layer QWP1, a geometric phase lens GPL, a second phase delay layer QWP2, a second polarization conversion layer LC2, and a third phase delay layer QWP3.

In the embodiment of FIG. 15, the roles of the first polarization conversion layer LC1, the first phase delay layer QWP1, the geometric phase lens GPL, the second phase delay layer QWP2, the second polarization conversion layer LC2, and the third phase delay layer QWP3 are substantially the same as those described with reference to FIG. 11 and FIG. 12, and therefore, a duplicate description thereof is not provided and repeated for conciseness.

The first polarization conversion layer LC1 may include a first substrate LC1_11, a first pixel electrode LC1_12, a first liquid crystal layer LC1_31, a first common electrode LC1_22, and a second substrate LC1_21.

The first substrate LC1_11 may be arranged on the filling layer FIL of the display panel 100 of FIG. 9 or the polarizing member POL of FIG. 10. The first substrate LC1_11 may overlap the plurality of variable focus areas FA1, FA2, FA3, and FA4.

The first pixel electrode LC1_12 may be arranged on one surface of the first substrate LC1_11. The one surface of the first substrate may be a surface opposite to (e.g., facing) the second substrate LC1_21. The other surface of the first substrate LC1_11 may be a surface opposite to (e.g., facing) the filling layer FIL or the polarizing member POL of the display panel 100.

The first pixel electrode LC1_12 may be arranged in each of the plurality of variable focus areas FA1, FA2, FA3, and FA4. The first pixel electrodes LC1_12 of two or more variable focus areas FA adjacent to each other may be spaced and/or apart (e.g., spaced apart or separated) from each other.

The first liquid crystal layer LC1_31 may be arranged between the first common electrode LC1_22 and the first pixel electrode LC1_12. The first liquid crystal layer LC1_31 may overlap the entire variable focus area FA.

The first liquid crystal layer LC1_31 may include a liquid crystal including a twisted nematic liquid crystal. If (e.g., when) the fourth driving voltage is applied to the first liquid crystal layer LC1_31, the liquid crystals of the first liquid crystal layer LC1_31 may be arranged in a spiral shape, and if (e.g., when) the fifth driving voltage is applied to the first liquid crystal layer LC1_31, the liquid crystals of the first liquid crystal layer LC1_31 may be arranged in a single row.

The second substrate LC1_21 may be arranged to (e.g., on) the first substrate LC1_11. The second substrate LC1_21 may overlap the plurality of variable focus areas FA1, FA2, FA3, and FA4. One surface of the second substrate LC1_21 may be a surface opposite to (e.g., facing) the one surface of the first substrate LC1_11.

The first common electrode LC1_22 may be arranged on the one surface of the second substrate LC1_21 opposite to (e.g., facing) the first substrate LC1_11. The first common electrode LC1_22 may be arranged across the entire variable focus area FA.

The first phase delay layer QWP1 may be arranged on the other surface of the second substrate LC1_21. The other surface of the second substrate LC1_21 is a surface opposite the one surface of the second substrate LC1_21. The first phase delay layer QWP1 may be arranged across the entire variable focus area FA.

The geometric phase lens GPL may be arranged on the first phase delay layer QWP1. The geometric phase lens GPL may be arranged across the entire variable focus area FA.

The second phase delay layer QWP2 may be arranged on the geometric phase lens GPL. The second phase delay layer QWP2 may be arranged across the entire variable focus area FA.

The second polarization conversion layer LC2 may include a third substrate LC2_11, a second pixel electrode LC2_12, a second liquid crystal layer LC2_31, a second common electrode LC2_22, and a fourth substrate LC2_21.

The third substrate LC2_11 may be arranged on the second phase delay layer QWP2. One surface of the third substrate may be a surface opposite to (e.g., facing) the fourth substrate LC2_21. The second pixel electrode LC2_12 may be arranged on the one surface of the third substrate LC2_11. The other surface of the third substrate LC2_11 may be a surface opposite to (e.g., facing) the second phase delay layer QWP2. The third substrate may overlap the plurality of variable focus areas FA1, FA2, FA3, and FA4.

The second pixel electrode LC2_12 may be arranged in each of the plurality of variable focus areas FA1, FA2, FA3, and FA4. The pixel electrodes LC2_12 of two or more variable focus areas FA adjacent to each other may be spaced and/or apart (e.g., spaced apart or separated) from each other.

The second liquid crystal layer LC2_31 may be arranged between the second common electrode LC2_22 and the second pixel electrode LC2_12. The second liquid crystal layer LC2_31 may overlap the entire variable focus area FA.

The second liquid crystal layer LC2_31 may include a liquid crystal including a twisted nematic liquid crystal. If (e.g., when) the sixth driving voltage is applied to the second liquid crystal layer LC2_31, the liquid crystals of the second liquid crystal layer LC2_31 may be arranged in a spiral shape, and if (e.g., when) the seventh driving voltage is applied to the second liquid crystal layer LC2_31, the liquid crystals of the second liquid crystal layer LC2_31 may be arranged in a single row.

The fourth substrate LC2_21 may be arranged to (e.g., on) the third substrate LC2_11. The fourth substrate LC2_21 may overlap the plurality of variable focus areas FA1, FA2, FA3, and FA4. One surface of the fourth substrate LC2_21 may be a surface opposite to (e.g., facing) the one surface of the third substrate LC2_11. The other surface of the fourth substrate LC2_21 may be a surface opposite to (e.g., facing) the third phase delay layer QWP3.

The second common electrode LC2_22 may be arranged on the one surface of the fourth substrate LC2_21. The second common electrode LC2_22 may be arranged across the entire variable focus area FA.

The third phase delay layer QWP3 may be arranged on the other surface of the fourth substrate LC2_21 on the second polarization conversion layer LC2. The third phase delay layer QWP3 may delay a phase of incident light by a wavelength. For example, in one or more embodiments, the third phase delay layer QWP3 may be a λ/4 (quarter-wave) plate, but embodiments of the present disclosure are not limited thereto.

Because the pixel electrodes LC1_12 of the first polarization conversion layer LC1 of the variable focus module TFM are spaced and/or apart (e.g., spaced apart or separated) from each other in the variable focus areas FA1, FA2, FA3, and FA4 adjacent to each other, and the pixel electrodes LC2_12 of the second polarization conversion layer LC2 of the variable focus module TFM are spaced and/or apart (e.g., spaced apart or separated) from each other in the variable focus areas FA1, FA2, FA3, and FA4 adjacent to each other, the voltage applied to the pixel electrodes LC1_12 and LC2_12 and the common electrodes LC1_22 and LC2_22 of the variable focus module TFM may be controlled or selected by the processor 12 or by the timing control unit 400 of the display device 10.

FIG. 15 illustrates the embodiment in which the variable focus module TFM is arranged across the entire variable focus area FA, but the variable focus module TFM may also be arranged in a tile format. If (e.g., when) the variable focus module TFM is arranged in the tile format, the variable focus module TFM may include four sub-variable focus modules respectively arranged in each of the variable focus areas FA1, FA2, FA3, and FA4.

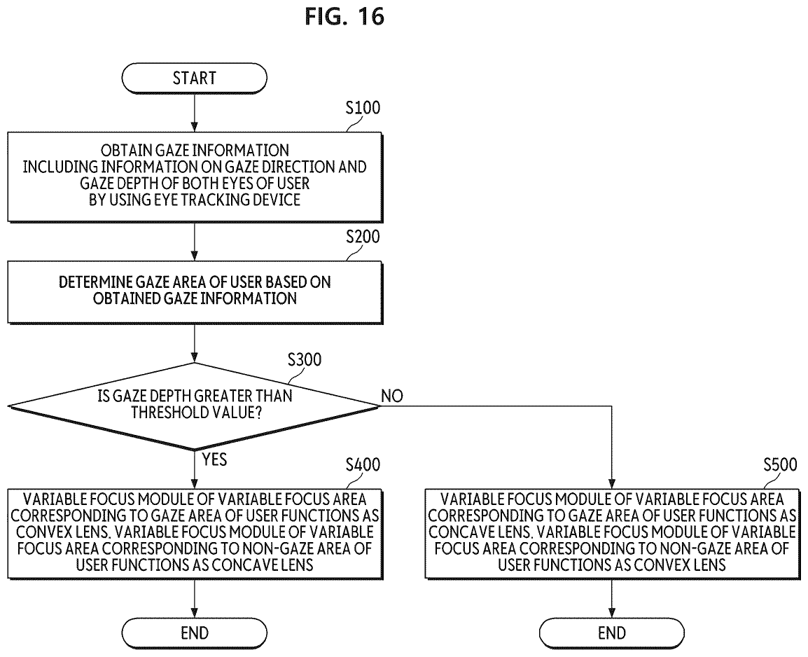

FIG. 16 is a flowchart illustrating a method for driving a head mounted display device according to one or more embodiments of the present disclosure.

FIG. 17 is a view illustrating a user gazing at one among the plurality of variable focus areas. FIG. 17 illustrates an example in which the user's two eyes 777_L and 777_R gaze at the fourth variable focus area FA4 among the plurality of variable focus areas FA1, FA2, FA3, and FA4.

Referring to FIG. 16, first, gaze information of both (e.g., simultaneously) eyes of a user is obtained by using the eye tracking device/module (15 in FIG. 2) (S100 in FIG. 16).

The eye tracking device/module (15 in FIG. 2) may include an image sensor such as a camera sensor, and captures the pupils of both (e.g., simultaneously) eyes of the user using the image sensor. The eye tracking device/module (15 in FIG. 2) obtains gaze information including the direction and depth of the user's gaze by analyzing the captured pupil images of both (e.g., simultaneously) eyes of the user.

Secondly, as illustrated in FIG. 17, one among the plurality of display areas DAA1, DAA2, DAA3, and DAA4 is determined as a user's gaze area based on the obtained gaze information (S200 of FIG. 16).

The eye tracking device/module (15 in FIG. 2) may calculate the display area that the user gazes at among the plurality of display areas DAA1, DAA2, DAA3, and DAA4 depending on the gaze direction of both (e.g., simultaneously) eyes 777_L and 777_R of the user. The eye tracking device/module (15 in FIG. 2) determines the calculated display area as the user's gaze area. The remaining display areas excluding the user's gaze area are determined as user's non-gaze areas. For example, as illustrated in FIG. 17, the fourth display area DAA4 that both (e.g., simultaneously) eyes 777_L and 777_R of the user gaze at may be determined as the gaze area. The first to third display areas DAA1, DAA2, and DAA3 excluding the fourth display area DAA4 may be determined as the non-gaze areas.

Thirdly, it is determined whether the depth of the gaze that the user gazes at the gaze area is greater than a threshold value based on the previously obtained gaze information (S300 in FIG. 16).

The eye tracking device/module (15 in FIG. 2) may calculate the depth of gaze of both (e.g., simultaneously) eyes 777_L and 777_R of the user. The eye tracking device/module (15 in FIG. 2) may determine whether the depth of the gaze that the user gazes at the gaze area is greater than the threshold value. For example, in FIG. 17, if (e.g., when) the user gazes at the fourth display area DAA4, which is the gaze area, with a far distance focus, the depth of the user's gaze may be greater than the threshold value. Unlike this, if (e.g., when) the user gazes at the fourth display area DAA4 with a near distance focus, the depth of the user's gaze may be less than or equal to the threshold value.

Fourthly, if (e.g., when) it is determined that the depth of the user's gaze is greater than the threshold value, the variable focus module TFM of the variable focus area FA corresponding to the user's gaze area functions as a convex lens, and the variable focus module TFM of the variable focus area corresponding to the user's non-gaze area functions as a concave lens (S400 in FIG. 16).

For example, in order for the variable focus module TFM of the fourth variable focus area FA4 corresponding to the user's gaze area to function as a convex lens, a fifth driving voltage and a seventh driving voltage are respectively applied to a first polarization conversion layer LC1 and a second polarization conversion layer LC2 of the variable focus module TFM corresponding to the gaze area. In this case, the first polarization conversion layer LC1 and the second polarization conversion layer LC2 may be to emit first linearly polarized light or second linearly polarized light that is incident as it is without changing the direction (i.e., polarization direction). Therefore, the first linearly polarized light emitted from the polarizing member POL of the display panel 100 may be incident on the first polarization conversion layer LC1 and emitted as it is without converting the polarization direction.

The first linearly polarized light emitted from the first polarization conversion layer LC1 may be converted into second circularly polarized light in the first phase delay layer QWP1 and incident on the geometric phase lens GPL. The geometric phase lens GPL on which the second circularly polarized light is incident may function as a convex lens and may convert the incident second circularly polarized light into first circularly polarized light and emit the first circularly polarized light.

The first circularly polarized light emitted from the geometric phase lens GPL may be converted into the first linearly polarized light in the second phase delay layer QWP2 and incident on the second polarization conversion layer LC2. The first linearly polarized light incident on the second polarization conversion layer LC2 may be emitted as it is without converting the polarization direction. The first linearly polarized light emitted from the second polarization conversion layer LC2 may be converted into the second circularly polarized light in the third phase delay layer QWP3 and incident on the pancake lens PCL.

In order for the variable focus modules TFM of the plurality of variable focus areas FA1, FA2, and FA3 corresponding to the user's non-gaze area to function as a concave lens, a fourth driving voltage and a sixth driving voltage are respectively applied to a first polarization conversion layer LC1 and a second polarization conversion layer LC2 of the variable focus module TFM corresponding to the non-gaze area. In this case, the first polarization conversion layer LC1 and the second polarization conversion layer LC2 may convert the incident linearly polarized light into a direction orthogonal to the direction of the incident linearly polarized light and output the converted light. Therefore, the first linearly polarized light emitted from the polarizing member POL of the display panel 100 may be incident on the first polarization conversion layer LC1 and converted into the second linearly polarized light and then emitted.

The second linearly polarized light emitted from the first polarization conversion layer LC1 may be converted into the first circularly polarized light in the first phase delay layer QWP1 and incident on the geometric phase lens GPL. The geometric phase lens GPL on which the first circularly polarized light is incident may function as a concave lens and may convert the incident first circularly polarized light into second circularly polarized light and emit the second circularly polarized light.

The second circularly polarized light emitted from the geometric phase lens GPL may be converted into the second linearly polarized light in the second phase delay layer QWP2 and incident on the second polarization conversion layer LC2. The second linearly polarized light incident on the second polarization conversion layer LC2 may be converted into the first linearly polarized light and emitted. The first linearly polarized light emitted from the second polarization conversion layer LC2 may be converted into the second circularly polarized light in the third phase delay layer QWP3 and incident on the pancake lens PCL.

Fifthly, if (e.g., when) it is determined that the depth of the user's gaze is not greater than the threshold value, the variable focus module TFM of the variable focus area FA corresponding to the user's gaze area functions as a concave lens. The variable focus module TFM of the variable focus area corresponding to the user's non-gaze area functions as a convex lens (S500 in FIG. 16).

For example, in order for the variable focus module TFM of the fourth variable focus area FA4 corresponding to the user's gaze area to function as a concave lens, a fourth driving voltage and a sixth driving voltage are respectively applied to a first polarization conversion layer LC1 and a second polarization conversion layer LC2 of the variable focus module TFM corresponding to the gaze area. In this case, the first polarization conversion layer LC1 and the second polarization conversion layer LC2 may convert the incident linearly polarized light into a direction orthogonal to the direction of the incident linearly polarized light and output the converted light. Therefore, the first linearly polarized light emitted from the polarizing member POL of the display panel 100 may be incident on the first polarization conversion layer LC1 and converted into the second linearly polarized light and then emitted.

The second linearly polarized light emitted from the first polarization conversion layer LC1 may be converted into the first circularly polarized light in the first phase delay layer QWP1 and incident on the geometric phase lens GPL. The geometric phase lens GPL on which the first circularly polarized light is incident may function as a concave lens and may convert the incident first circularly polarized light into second circularly polarized light and emit the second circularly polarized light.

The second circularly polarized light emitted from the geometric phase lens GPL may be converted into the second linearly polarized light in the second phase delay layer QWP2 and incident on the second polarization conversion layer LC2. The second linearly polarized light incident on the second polarization conversion layer LC2 may be converted into the first linearly polarized light and emitted. The first linearly polarized light emitted from the second polarization conversion layer LC2 may be converted into the second circularly polarized light in the third phase delay layer QWP3 and incident on the pancake lens PCL.

In order for the variable focus modules TFM of the plurality of variable focus areas FA1, FA2, and FA3 corresponding to the user's non-gaze area to function as a convex lens, a fifth driving voltage and a seventh driving voltage are respectively applied to a first polarization conversion layer LC1 and a second polarization conversion layer LC2 of the variable focus module TFM corresponding to the non-gaze area. In this case, the first polarization conversion layer LC1 and the second polarization conversion layer LC2 may be to emit first linearly polarized light or second linearly polarized light that is incident as it is without changing the direction. Therefore, the first linearly polarized light emitted from the polarizing member POL of the display panel 100 may be incident on the first polarization conversion layer LC1 and emitted as it is without converting the polarization direction.

The first linearly polarized light emitted from the first polarization conversion layer LC1 may be converted into second circularly polarized light in the first phase delay layer QWP1 and incident on the geometric phase lens GPL. The geometric phase lens GPL on which the second circularly polarized light is incident may function as a convex lens and may convert the incident second circularly polarized light into first circularly polarized light and emit the first circularly polarized light.

The first circularly polarized light emitted from the geometric phase lens GPL may be converted into the first linearly polarized light in the second phase delay layer QWP2 and incident on the second polarization conversion layer LC2. The first linearly polarized light incident on the second polarization conversion layer LC2 may be emitted as it is without converting the polarization direction. The first linearly polarized light emitted from the second polarization conversion layer LC2 may be converted into the second circularly polarized light in the third phase delay layer QWP3 and incident on the pancake lens PCL.

As described with reference to FIG. 16 and FIG. 17, it may reduce or prevent an occurrence of fatigue in the user's eyes due to the mismatch in focus when viewing the near and far objects in a virtual reality image by varying a focal length in a corresponding variable focus area of the variable focus module TFM, depending on whether the user gazes at a near or far distance in the display area.

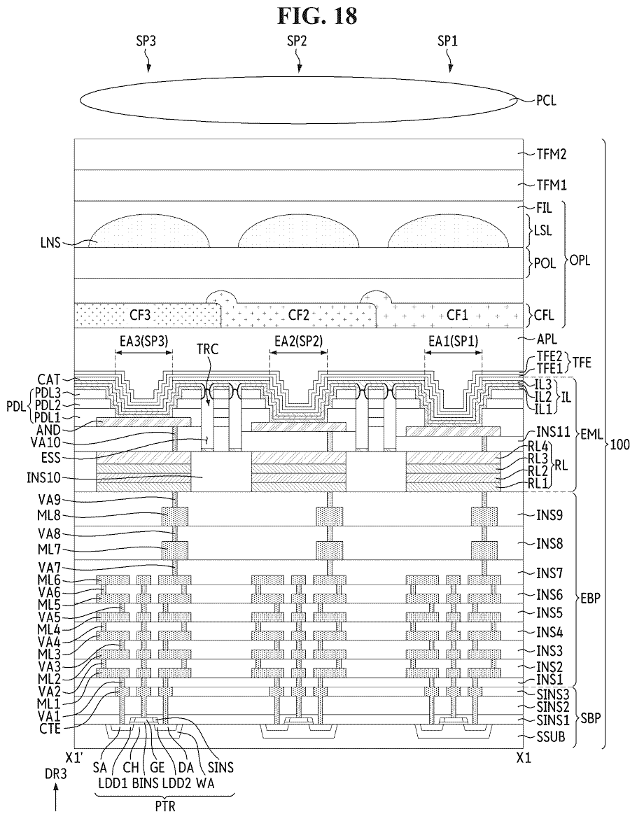

FIG. 18 is a cross-sectional view illustrating still another example of the display device taken along the line X1-X1′ of FIG. 7.

The embodiment of FIG. 18 differs from the embodiment of FIG. 9 in applying a plurality of variable focus modules TFM. When the plurality of variable focus modules TFM are applied, the number of focal lengths of the variable focus modules TFM may be improved to 2ⁿ. Here, n is the number of variable focus modules TFM, and n may be a natural number. For example, as illustrated in FIG. 18, if (e.g., when) the variable focus module TFM has two variable focus modules TFM, the display device may express four (or four steps) focal lengths.

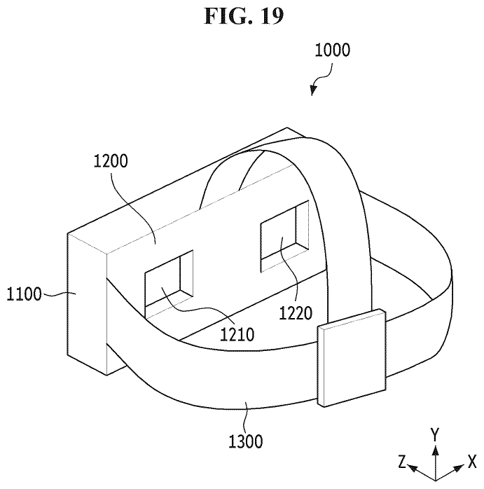

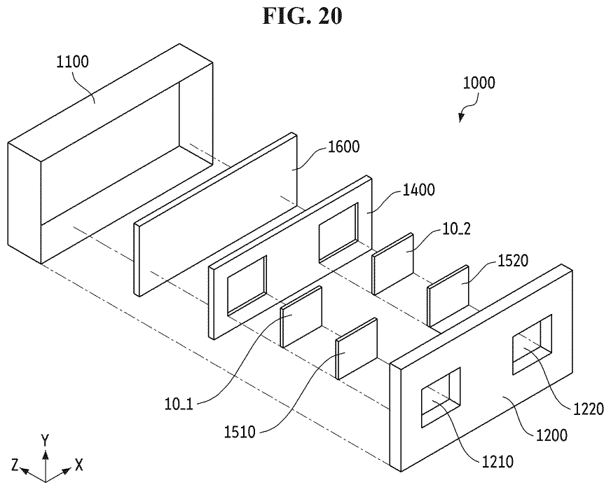

FIG. 19 is a perspective view illustrating a head mounted display device according to one or more embodiments of the present disclosure. FIG. 20 is an exploded perspective view illustrating an example of the head mounted display device of FIG. 19 according to one or more embodiments.

Referring to FIG. 19 and FIG. 20, a head mounted display device 1000 according to one or more embodiments includes a first display device 10_1, a second display device 10_2, a display device accommodating portion 1100, an accommodating portion cover 1200, a first eyepiece 1210, a second eyepiece 1220, a head mounting band 1300, a middle frame 1400, a first optical member 1510, a second optical member 1520, and a control circuit board 1600.

The first display device 10_1 provides an image to a user's left eye, and the second display device 10_2 provides an image to a user's right eye. Because each of the first display device 10_1 and the second display device 10_2 is substantially the same as the display device 10 described with reference to FIGS. 3 to 10, the descriptions of the first display device 10_1 and the second display device 10_2 are omitted.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and may be arranged between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device accommodating portion 1100. The control circuit board 1600 may be connected to the first display device 10_1 and the second display device 10_2 through a connector. The control circuit board 1600 may convert an image source input from the outside into digital video data DATA, and may be to transmit the digital video data DATA to the first display device 10_1 and the second display device 10_2 through the connector.

In one or more embodiments, the control circuit board 1600 may be to transmit digital video data DATA corresponding to a left eye image improved or optimized for the user's left eye to the first display device 10_1, and may be to transmit digital video data DATA corresponding to a right eye image improved or optimized for the user's right eye to the second display device 10_2. In one or more embodiments, the control circuit board 1600 may be to transmit the same digital video data DATA to the first display device 10_1 and the second display device 10_2.

The display device accommodating portion 1100 serves to accommodate the first display device 10_1, the second display device 10_2, the middle frame 1400, the first optical member 1510, the second optical member 1520, and the control circuit board 1600. The accommodating portion cover 1200 is arranged to cover one opened surface of the display device accommodating portion 1100. The accommodating portion cover 1200 may include a first eyepiece 1210 at which the user's left eye gazes and a second eyepiece 1220 at which the user's right eye gazes. It is illustrated in FIGS. 19 and 20 that the first eyepiece 1210 and the second eyepiece 1220 are separately arranged, but embodiments of the present disclosure are not limited thereto. In one or more embodiments, the first eyepiece 1210 and the second eyepiece 1220 may be integrated into one.

The first eyepiece 1210 may be aligned with the first display device 10_1 and the first optical member 1510, and the second eyepiece 1220 may be aligned with the second display device 10_2 and the second optical member 1520. Therefore, the user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

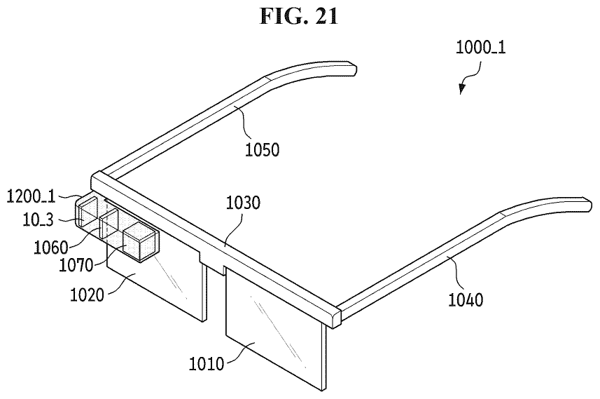

The head mounting band 1300 serves to fix the display device accommodating portion 1100 to a user's head so that the first eyepiece 1210 and the second eyepiece 1220 of the accommodating portion cover 1200 are arranged on the user's left and right eyes, respectively. In one or more embodiments, when the display device accommodating portion 1200 is implemented in a lightweight and small size, the head mounted display device 1000 may include eyeglass frames as illustrated in FIG. 21 instead of the head mounting band 1300.

FIG. 21 is a perspective view illustrating a head mounted display device according to one or more embodiments of the present disclosure.

Referring to FIG. 21, a head mounted display device 1000_1 according to one or more embodiments may be a glasses-type (kind) display device in which a display device accommodating portion 1200_1 is implemented in a lightweight and small size. The head mounted display device 1000_1 according to one or more embodiments may include a display device 10_3, a left eye lens 1010, a right eye lens 1020, a support frame 1030, eyeglass frame legs 1040 and 1050, an optical member 1600, a light path conversion member 1070, and the display device accommodating portion 1200_1.

The display device accommodating portion 1200_1 may include the display device 10_3, the optical member 1600, and the light path conversion member 1070. As an image displayed on the display device 10_3 is magnified by the optical member 1600 and a light path thereof is changed by the light path conversion member 1070, the image may be provided to the user's right eye through the right eye lens 1020. Accordingly, the user may view an augmented reality image in which a virtual image displayed on the display device 10_3 and a real image viewed through the right eye lens 1020 are combined.

It is illustrated in FIG. 21 that the display device accommodating portion 1200_1 is arranged at a right distal end of the support frame 1030, but embodiments of the present disclosure are not limited thereto. For example, in one or more embodiments, the display device accommodating portion 1200_1 may be arranged at a left distal end of the support frame 1030, and in these embodiments, the image of the display device 10_3 may be provided to the user's left eye. In one or more embodiments, the display device accommodating portions 1200_1 may be arranged at both (e.g., simultaneously) the left and right distal ends of the support frame 1030. In these embodiments, the user may view the image displayed on the display device 10_3 through both (e.g., simultaneously) the user's left and right eyes.

In the present disclosure, the term “real image” may refer to an image that is the collection of focus points actually made by converging/diverging rays. The term “virtual image” may refer to an image that is the collection of focus points made by extensions of diverging or converging rays.

In the context of the present application and unless otherwise defined, the terms “use,” “using,” and “used” may be considered synonymous with the terms “utilize,” “utilizing,” and “utilized,” respectively.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood, however, that the aspects of embodiments of the present disclosure are not restricted to the those set forth herein. The above and other aspects of the present disclosure will become more apparent to one of ordinary skill in the art to which the present disclosure pertains by referencing the appended claims, with functional equivalents thereof to be included therein. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device, comprising:
a display panel configured to emit light; and
a variable focus module on a surface of the display panel and configured to adjust a focal length of the light,
wherein the variable focus module comprises:
a first polarization control layer configured to emit incident light as first circularly polarized light or second circularly polarized light; and
a geometric phase lens configured to function as a convex lens having a first focal length when the first circularly polarized light is incident, and to function as a concave lens having a second focal length when the second circularly polarized light is incident.

2. The display device of claim 1, wherein the variable focus module further comprises a second polarization control layer configured to emit the first circularly polarized light or the second circularly polarized light incident from the geometric phase lens as the second circularly polarized light.

3. The display device of claim 2, wherein the light emitted from the display panel is first linearly polarized light having an optical axis in a first direction, and
the first polarization control layer comprises:
a first polarization conversion layer configured to emit the first linearly polarized light as it is or to convert the first linearly polarized light into second linearly polarized light having an optical axis in a second direction orthogonal to the first direction; and
a first phase delay layer configured to emit the first circularly polarized light by delaying a phase of the first linearly polarized light, or to emit the second circularly polarized light by delaying a phase of the second linearly polarized light.

4. The display device of claim 3, wherein the second polarization control layer comprises:
a second phase delay layer configured to emit the first linearly polarized light by delaying a phase of the first circularly polarized light incident from the geometric phase lens, or to emit the second linearly polarized light by delaying a phase of the second circularly polarized light;
a second polarization conversion layer configured to emit the first linearly polarized light incident from the second phase delay layer as it is or to convert the second linearly polarized light into the first linearly polarized light; and
a third phase delay layer configured to emit the second circularly polarized light by delaying the phase of the first linearly polarized light emitted from the second polarization conversion layer.

5. The display device of claim 1, wherein the display panel comprises:
a linear polarizer configured to emit the light emitted from inside the display panel or light incident from outside the display panel as linearly polarized light vibrating in one direction; and
a fourth phase delay layer configured to delay a phase of the linearly polarized light or a circularly polarized light.

6. The display device of claim 1, further comprising a pancake lens configured to magnify an image implemented on the display panel.

7. The display device of claim 6, wherein the pancake lens comprises:
a semitransparent mirror configured to transmit a portion of light incident on the pancake lens and reflecting another portion of the light;
a first lens on the semitransparent mirror;
a second lens on the first lens;
a fifth phase delay layer on one surface of the second lens and having a phase delay of λ/4;
a reflective polarizing layer on the fifth phase delay layer, and configured to transmit light parallel to a transmission axis, and reflect light orthogonal to the transmission axis; and
a third lens on the reflective polarizing layer.

8. The display device of claim 1, further comprising an eye tracking module,
wherein the display panel comprises a plurality of display areas,
wherein the eye tracking module is configured to determine which area among the plurality of display areas a gaze of an eye is directed to, and to track a depth of the gaze, and
wherein the variable focus module comprises a plurality of variable focus areas respectively corresponding to the plurality of display areas, and is configured to adjust a focal length of a variable focus area determined by the eye tracking module as an area that the eye is not gazed at among the plurality of variable focus areas according to the depth of the gaze.

9. The display device of claim 8, wherein the light emitted from the display panel is first linearly polarized light having an optical axis in a first direction, and
the variable focus module comprises:
a first polarization conversion layer configured to emit the first linearly polarized light as it is according to a first driving voltage, or to convert the first linearly polarized light into second linearly polarized light having an optical axis in a second direction orthogonal to the first direction according to a second driving voltage; and
a first phase delay layer configured to emit the first circularly polarized light by delaying a phase of the first linearly polarized light, or to emit the second circularly polarized light by delaying a phase of the second linearly polarized light.

10. The display device of claim 9, wherein the eye tracking module further comprises:
a variable focus circuit configured to apply the first driving voltage to the first polarization conversion layer when the depth of the gaze is greater than a first threshold value, and to apply the second driving voltage to the first polarization conversion layer when the depth of the gaze is less than or equal to the first threshold value.

11. The display device of claim 10, wherein a variable focus area among the plurality of variable focus areas determined by the eye tracking module is defined as a gaze area, and a variable focus area among the plurality of variable focus areas not determined by the eye tracking module is defined as a non-gaze area, and
wherein:
when the first driving voltage is applied to the first polarization conversion layer of the gaze area, then the second driving voltage is applied to the first polarization conversion layer of a plurality of non-gaze areas; or
when the second driving voltage is applied to the first polarization conversion layer of the gaze area, then the first driving voltage is applied to the first polarization conversion layer of the plurality of non-gaze areas.

12. The display device of claim 8, wherein when the depth of the gaze is greater than a first threshold value, the variable focus module of the variable focus area determined by the eye tracking module has the first focal length, and
when the depth of the gaze is less than or equal to the first threshold value, the variable focus module of the variable focus area determined by the eye tracking module has the second focal length.

13. The display device of claim 10, wherein the first polarization conversion layer comprises:
first and second substrates opposite to each other;
a plurality of first pixel electrodes on a surface of the first substrate opposite to the second substrate and respectively corresponding to the plurality of variable focus areas;
a first common electrode on a surface of the second substrate opposite to the first substrate and overlapping the plurality of variable focus areas; and
a first liquid crystal layer between the first substrate and the second substrate.

14. The display device of claim 9, wherein the variable focus module further comprises:
a second phase delay layer configured to emit the first linearly polarized light by delaying a phase of the first circularly polarized light incident from the geometric phase lens, or to emit the second linearly polarized light by delaying a phase of the second circularly polarized light;
a second polarization conversion layer configured to emit the first linearly polarized light incident from the second phase delay layer as it is or to convert the second linearly polarized light into the first linearly polarized light; and
a third phase delay layer configured to emit the second circularly polarized light by delaying the phase of the first linearly polarized light emitted from the second polarization conversion layer.

15. The display device of claim 14, wherein the second polarization conversion layer comprises:
third and fourth substrates opposite to each other;
a plurality of second pixel electrodes on a surface of the third substrate opposite to the fourth substrate and respectively corresponding to the plurality of variable focus areas;
a second common electrode on a surface of the fourth substrate opposite to the third substrate and overlapping the plurality of variable focus areas; and
a second liquid crystal layer between the third substrate and the fourth substrate.

16. The display device of claim 1, wherein the variable focus module comprises a plurality of sub-variable focus modules overlapping each other in a thickness direction of the display panel.

17. A method, comprising:
obtaining gaze information of both eyes of a user;
determining a gaze area of the user and calculating a gaze depth based on the obtained gaze information;
adjusting incident light to a first focal length in a variable focus area corresponding to the gaze area of the user among a plurality of variable focus areas of a variable focus module, when the gaze depth is greater than a threshold value; and
adjusting the incident light to a second focal length in the variable focus area corresponding to the gaze area of the user, when the gaze depth is less than or equal to the threshold value,
wherein the method is a method for driving a display device.

18. The method of claim 17, wherein a variable focus area other than the gaze area of the user is defined as a non-gaze area, and the method further comprises:
adjusting the incident light to the second focal length in a plurality of non-gaze areas, when the gaze depth is greater than the threshold value; and
adjusting the incident light to the first focal length in a plurality of non-gaze areas, when the gaze depth is less than or equal to the threshold value.

19. The method of claim 17, wherein the first focal length corresponds to a focal length of a virtual image, and the second focal length corresponds to a focal length of a real image.

20. An electronic device comprising:
a display module configured to display an image; and
a processor configured to transmit a video data signal to the display module,
wherein the display module comprises:
a display panel configured to emit light; and
a variable focus module on a surface of the display panel and configured to adjust a focal length of the light, and
the variable focus module comprises:
a first polarization control layer configured to emit incident light as first circularly polarized light or second circularly polarized light; and
a geometric phase lens configured to function as a convex lens having a first focal length when the first circularly polarized light is incident, and to function as a concave lens having a second focal length when the second circularly polarized light is incident.
